(19) United States
(12) Patent Application Publication
(10) Pub. No.: US 2026/0314123 A1
(43) Pub. Date: Oct. 8, 2026

(54) LIGHT-EMITTING DEVICE AND DISPLAY APPARATUS INCLUDING THE SAME

(71) Applicant: SAMSUNG ELECTRONICS CO., LTD., Suwon-si (KR)

(72) Inventors: Youngtek OH, Suwon-si (KR); Joosung KIM, Suwon-si (KR); Dongchul SHIN, Suwon-si (KR); Kyungwook HWANG, Suwon-si (KR)

(73) Assignee: SAMSUNG ELECTRONICS CO., LTD., Suwon-si (KR)

(21) Appl. No.: 19/341,853

(22) Filed: Sep. 26, 2025

(30) Foreign Application Priority Data
Apr. 2, 2025 (KR) 10-2025-0043118

(51) Int. Cl. H10H 20/831

(52) U.S. Cl. CPC H10H 20/8312; H10H 20/8314

(57) ABSTRACT

According to an aspect of the disclosure, a light-emitting device capable of obtaining a sufficient light quantity with a low driving voltage and a display apparatus including the light-emitting device may be provided. The light-emitting device may include a light-emitting portion, a first common electrode under the light-emitting portion, a second common electrode under the light-emitting portion, and separation layers on side surfaces of light-emitting structures of the light-emitting portion.

### CROSS-REFERENCE TO RELATED APPLICATION

This application is based on and claims priority under 35 U.S.C. § 119 to Korean Patent Application No. 10-2025-0043118, filed on Apr. 2, 2025, in the Korean Intellectual Property Office, the disclosure of which is incorporated by reference herein in its entirety.

### BACKGROUND

### 1. Field

The disclosure relates to a light-emitting device and a display apparatus including the same.

### 2. Description of Related Art

Light-emitting devices such as light-emitting diodes (LEDs) are known as next-generation light sources having advantages such as a long lifespan, low power consumption, fast response time, and environmental friendliness, as compared to light sources of the related art. Owing to these advantages, the industrial demand for such light-emitting devices has increased. LEDs are commonly applied to various products such as lighting devices and display apparatuses.

Recently, ultra-small LEDs having microscale or nanoscale dimensions have been developed, and these are referred to as micro-LEDs. Micro-LEDs are applied to relatively large display apparatuses such as televisions, and further attempts have been made to apply micro-LEDs to small display apparatuses, such as displays for augmented reality (AR) devices. Micro-LEDs applied to small display apparatuses are extremely small, about several micrometers in size, making it difficult to secure an emission area and luminous efficiency that are capable of achieving sufficient light quantity. In a micro-LED in which red-green-blue (RGB) subpixels are vertically arranged, the emission area is reduced due to electrodes used to drive each subpixel, which may lead to a decrease in the luminous efficiency of the micro-LED.

### SUMMARY

Provided are a light-emitting device capable of obtaining a sufficient light quantity with a low driving voltage, and a display apparatus including the light-emitting device.

Provided are a light-emitting device with improved luminous efficiency and a display apparatus including the light-emitting device.

Additional aspects will be set forth in part in the description which follows and, in part, will be apparent from the description, or may be learned by practice of the presented example embodiments of the disclosure.

According to an aspect of the disclosure, a light-emitting device may include: a light-emitting portion including a first light-emitting structure and a second light-emitting structure on the first light-emitting structure in a first direction, the first light-emitting structure and the second light-emitting structure configured to emit light of a same wavelength as each other, wherein a width of the second light-emitting structure is greater than a width of the first light-emitting structure, each of the first light-emitting structure and the second light-emitting structure includes a first conductivity type semiconductor layer, an active layer, and a second conductivity type semiconductor layer, and the active layer is between the first conductivity type semiconductor layer and the second conductivity type semiconductor layer in the first direction; a first common electrode including: a first common portion under the light-emitting portion in a second direction opposite to the first direction; and a plurality of first electrode portions extending from the first common portion such as to respectively contact the first conductivity type semiconductor layer of the first light-emitting structure and the first conductivity type semiconductor layer of the second light-emitting structure, wherein at least one of the plurality of first electrode portions includes a conductive via structure; a second common electrode including: a second common portion under the light-emitting portion in the second direction; and a plurality of second electrode portions extending from the second common portion in the first direction such as to respectively contact a side surface of the second conductivity type semiconductor layer of the first light-emitting structure and a side surface of the second conductivity type semiconductor layer of the second light-emitting structure, wherein the plurality of second electrode portions are spaced apart from each other in a third direction crossing the first direction; and a plurality of separation layers configured to insulate the side surface of the second conductivity type semiconductor layer of the first light-emitting structure, the side surface of the second conductivity type semiconductor layer of the second light-emitting structure, a side surface of the active layer of the first light-emitting structure, and a side surface of the active layer of the second light-emitting structure from the plurality of second electrode portions.

The plurality of second electrode portions may surround a side portion of the light-emitting portion.

The light-emitting device may further include a protective layer between the plurality of second electrode portions.

In each of the first light-emitting structure and the second light-emitting structure, the active layer may be on the first conductivity type semiconductor layer in the first direction, and the second conductivity type semiconductor layer may be on the active layer in the first direction.

In the first light-emitting structure and the second light-emitting structure, a width of the active layer and a width of the first conductivity type semiconductor layer may be less than a width of the second conductivity type semiconductor layer, the plurality of second electrode portions may respectively contact side surfaces of the second conductivity type semiconductor layer of the first light-emitting structure and the second conductivity type semiconductor layer of the second light-emitting structure, and the plurality of second electrode portions may be spaced apart from each other in the third direction on a side portion of the light-emitting portion.

Two separation layers from among the plurality of separation layers may extend beyond the active layer of the first light-emitting structure and the active layer of the second light-emitting structure, respectively.

A first electrode portion, from among the plurality of first electrode portions, may contact the first conductivity type semiconductor layer of the second light-emitting structure, and the first electrode portion may include the conductive via structure.

In the first light-emitting structure and the second light-emitting structure, the active layer may be on the second conductivity type semiconductor layer in the first direction, and the first conductivity type semiconductor layer may be on the active layer in the first direction.

A width of the second conductivity type semiconductor layer of the second light-emitting structure may be less than a width of the active layer of the second light-emitting structure and a width of the first conductivity type semiconductor layer of the second light-emitting structure, the second common portion may contact a lower surface of the second conductivity type semiconductor layer of the first light-emitting structure, and at least one of the plurality of second electrode portions may contact the side surface of the second conductivity type semiconductor layer of the second light-emitting structure, and the plurality of second electrode portions may be spaced apart from each other in the third direction on a side portion of the light-emitting portion.

A separation layer, from among the plurality of separation layers, may be between one of the plurality of second electrode portions and the first light-emitting structure, and the one of the plurality of second electrode portions may contact the side surface of the second conductivity type semiconductor layer of the second light-emitting structure.

A first separation layer, from among the plurality of separation layers, may extend to the second conductivity type semiconductor layer of the first light-emitting structure, and a second separation layer, from among the plurality of separation layers, may extend to the second conductivity type semiconductor layer of the second light-emitting structure.

The plurality of first electrode portions may include conductive via structures.

The first light-emitting structure and the second light-emitting structure may be configured to emit one from among blue light, green light, and red light.

The first light-emitting structure and the second light-emitting structure may be configured to emit red light.

The light-emitting may further include a lens on the light-emitting portion in the first direction.

The second common electrode may include a reflective electrode material.

The first conductivity type semiconductor layer and the second conductivity type semiconductor layer may be a p-type semiconductor layer and an n-type semiconductor layer, respectively, the first common electrode may be a p-common electrode, and the second common electrode may be an n-common electrode.

According to an aspect of the disclosure, a light-emitting device may include: a light-emitting portion including a first light-emitting structure and a second light-emitting structure on the first light-emitting structure in a first direction, the first light-emitting structure and the second light-emitting structure configured to emit light of a same wavelength as each other, each of the first light-emitting structure and the second light-emitting structure including a first conductivity type semiconductor layer, an active layer, and a second conductivity type semiconductor layer, wherein the active layer is between the first conductivity type semiconductor layer and the second conductivity type semiconductor layer in the first direction, wherein a side surface of the second conductivity type semiconductor layer of the first light-emitting structure includes a first concave portion including a stepped shape that is concave with respect to a side surface of the active layer of the first light-emitting structure and a side surface of the first conductivity type semiconductor layer of the first light-emitting structure, wherein a side surface of the second conductivity type semiconductor layer of the second light-emitting structure includes a second concave portion including a stepped shape that is concave with respect to a side surface of the active layer of the second light-emitting structure and a side surface of the first conductivity type semiconductor layer of the second light-emitting structure, and wherein the light-emitting device further includes: a first common electrode including: a first common portion under the light-emitting portion in a second direction opposite to the first direction; and a plurality of first electrode portions extending from the first common portion such as to respectively contact the first conductivity type semiconductor layer of the first light-emitting structure and the first conductivity type semiconductor layer of the second light-emitting structure, wherein at least one of the plurality of first electrode portions includes a conductive via structure; a separation layer on a side portion of the light-emitting portion, wherein the first concave portion and the second concave portion are exposed from the separation layer; and a second common electrode including: a second common portion under the light-emitting portion in the second direction; and a second electrode portion extending from the second common portion in the first direction along an outer surface of the separation layer such as to contact, via the first concave portion, the side surface of the second conductivity type semiconductor layer of the first light-emitting structure, and contact, via the second concave portion, the side surface of the second conductivity type semiconductor layer of the second light-emitting structure.

According to an aspect of the disclosure, a display apparatus may include: a display panel including: a plurality of light-emitting devices; and a driving circuit configured to switch the plurality of light-emitting devices on and off; and a controller configured to input an on-off switching signal of the plurality of light-emitting devices to the driving circuit according to an image signal, wherein at least one of the plurality of light-emitting devices includes the light-emitting device.

The light-emitting device is configured to emit red light.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of a light-emitting device according to an embodiment;

FIG. 2 is a schematic cross-sectional view of a light-emitting device according to an embodiment;

FIGS. 3 and 4 illustrate embodiments of a planar arrangement of a first common portion of a first common electrode and a second common portion of a second common electrode;

FIG. 5 is a schematic cross-sectional view of a light-emitting device according to an embodiment;

FIG. 6 is a schematic cross-sectional view of a light-emitting device according to an embodiment;

FIGS. 7A through 7Q illustrate an example of a method of manufacturing the light-emitting devices of FIGS. 1 and 2;

FIGS. 8A through 8O illustrate an example of a method of manufacturing the light-emitting device of FIG. 5;

FIGS. 9A through 9N illustrate an example of a method of manufacturing the light-emitting device of FIG. 6;

FIGS. 10A and 10B are flowcharts of embodiments of a method of manufacturing a light-emitting device;

FIG. 11 is a schematic view illustrating an embodiment of a display apparatus;

FIG. 12 is a schematic view illustrating an embodiment of a projection display apparatus;

FIG. 13 illustrates an example of the arrangement of light-emitting devices of a display panel illustrated in FIG. 12;

FIG. 14 is a block diagram illustrating an embodiment of an electronic device including a display;

FIG. 15 illustrates an embodiment of a mobile device as an application example of an electronic device;

FIG. 16 illustrates an embodiment of a head-up display apparatus for a vehicle as an application example of an electronic device;

FIG. 17 illustrates an embodiment of augmented reality glasses or virtual reality glasses as an application example of an electronic device;

FIG. 18 illustrates an embodiment of a large signage as an application example of an electronic device; and

FIG. 19 illustrates an embodiment of a wearable display as an application example of an electronic device.

### DETAILED DESCRIPTION

Reference will now be made in detail to non-limiting example embodiments (e.g., a light-emitting device and a display apparatus including the same) of the disclosure, examples of which are illustrated in the accompanying drawings, wherein like reference numerals refer to the like elements throughout. In the drawings, the sizes of elements may be exaggerated for clarity and for convenience of explanation. In this regard, embodiments of the disclosure may have different forms and should not be construed as being limited to the descriptions set forth herein. Accordingly, example embodiments are merely described below, by referring to the figures, to explain example aspects of the disclosure. As used herein, the term “and/or” includes any and all combinations of one or more of the associated listed items. Expressions such as “at least one of,” when preceding a list of elements, modify the entire list of elements and do not modify the individual elements of the list.

It will be understood that when a layer is referred to as being “on” another layer or substrate, it can be directly on the other layer or substrate, or intervening layers may also be present. An expression used in the singular encompasses the expression of the plural, unless it has a clearly different meaning in the context. The terms “comprises” and/or “comprising” or “includes” and/or “including” when used in this specification, specify the presence of stated elements, but do not preclude the presence or addition of one or more other elements.

The use of the terms “a” and “an” and “the” and similar referents are to be construed to cover both the singular and the plural. The operations that constitute a method described herein can be performed in any suitable order unless otherwise indicated herein or otherwise clearly contradicted by context, and embodiments of the disclosure are not limited to the stated order.

The connecting lines, or connectors shown in the various figures presented are intended to represent non-limiting example functional relationships and/or physical or logical couplings between the various elements. It should be noted that many alternative or additional functional relationships, physical connections, or logical connections may be present in a practical device of the disclosure.

The use of any and all examples, and example language provided herein, is intended merely to better illuminate the disclosure and does not pose a limitation on the scope of the disclosure unless otherwise stated.

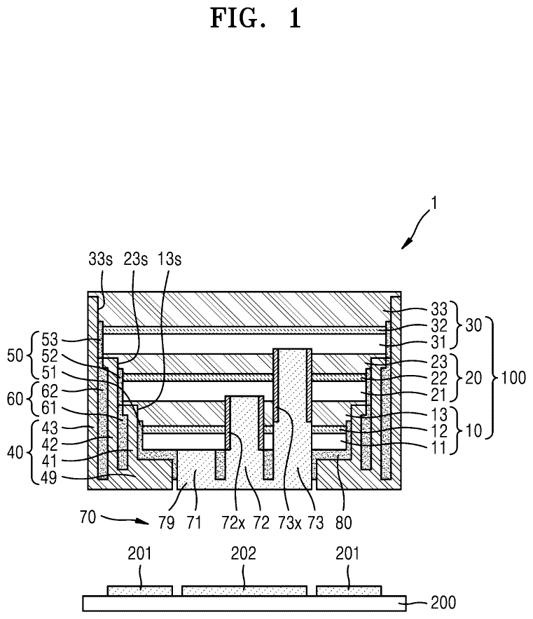

FIG. 1 is a schematic cross-sectional view of a light-emitting device 1 according to an embodiment. The light-emitting device 1 of the present embodiment is a vertically stacked light-emitting device in which a plurality of subpixels are vertically stacked. The light-emitting device 1 may be, for example, a micro-light-emitting diode (LED).

Referring to FIG. 1, the light-emitting device 1 may include a light-emitting portion 100 including a plurality of light-emitting structures that are vertically stacked and emit light of the same wavelength, and a plurality of electrodes for driving the plurality of light-emitting structures.

The plurality of light-emitting structures may have a width (e.g., a width in a horizontal direction orthogonal to a stacking direction) that increases in the stacking direction. The light-emitting device 1 may correspond to one pixel or one subpixel in a display apparatus. Each of the plurality of light-emitting structures may include a first conductivity type semiconductor layer, an active layer having a quantum well structure, and a second conductivity type semiconductor layer which are vertically epitaxially grown. The plurality of light-emitting structures may be vertically epitaxially grown and stacked to form the light-emitting portion 100. The plurality of light-emitting structures may be individually epitaxially grown and then sequentially transferred and stacked to form the light-emitting portion 100.

The plurality of electrodes may include a first common electrode common to first conductivity type semiconductor layers of the plurality of light-emitting structures, and a second common electrode common to second conductivity type semiconductor layers of the plurality of light-emitting structures. The first common electrode may include a first common portion provided under the light-emitting portion 100, and a plurality of first electrode portions each extending from the first common portion and respectively contacting the first conductivity type semiconductor layers of the plurality of light-emitting structures. At least some of the plurality of first electrode portions may have a conductive via structure passing through at least one of the plurality of light-emitting structures. The second common electrode may include a second common portion disposed under the light-emitting portion 100, and a plurality of second electrode portions each extending from the second common portion in the stacking direction. At least some of the plurality of second electrode portions may be arranged on a side portion of the light-emitting portion 100 to be spaced apart from each other in the horizontal direction orthogonal to the stacking direction, At least some of the plurality of second electrode portions may respectively contact side surfaces of second conductivity type semiconductor layers of at least some of the plurality of light-emitting structures. At least some of the plurality of second electrode portions may partially or entirely surround the side portion of the light-emitting portion 100,

[symbol]

The light-emitting portion 100 may be formed of a Group III-V nitride semiconductor material. Examples of the Group III-V nitride semiconductor material may include GaN, InGaN, AlInGaN, and AlGaInP. For example, the light-emitting portion 100 may be formed of a GaN-based semiconductor material. The light-emitting portion 100 may include a plurality of light-emitting structures. In the active layer of each of the plurality of light-emitting structures, bandgap energy may be controlled according to a composition ratio of indium (In) in a material layer including indium (In) to determine an emission wavelength band. In the present embodiment, the light-emitting portion 100 may include a first light-emitting structure 10, a second light-emitting structure 20, and a third light-emitting structure 30 that are sequentially stacked in a light-emitting direction. However, embodiments of the disclosure are not limited thereto, and the light-emitting portion 100 may include two or four or more light-emitting structures. In the present embodiment, the first light-emitting structure 10, the second light-emitting structure 20, and the third light-emitting structure 30 may emit red light (e.g., light in a wavelength range of 630±20 nm). However, embodiments of the disclosure are not limited thereto, and the first light-emitting structure 10, the second light-emitting structure 20, and the third light-emitting structure 30 may emit light of a wavelength band other than red light. For example, the first light-emitting structure 10, the second light-emitting structure 20, and the third light-emitting structure 30 may emit green light (e.g., light in a wavelength range of 530±20 nm), or may emit blue light (e.g., light in a wavelength range of 460±20 nm).

The first light-emitting structure 10 may be a lowermost light-emitting structure of the light-emitting portion 100. The second light-emitting structure 20 may be stacked on the first light-emitting structure 10, and the third light-emitting structure 30 may be stacked on the second light-emitting structure 20. The third light-emitting structure 30 may be an uppermost light-emitting structure of the light-emitting portion 100. The stacking direction of the first light-emitting structure 10, the second light-emitting structure 20, and the third light-emitting structure 30 may be the same as the light-emitting direction. The light-emitting portion 100 according to an embodiment may have a shape (e.g., a stepped shape) whose width increases in the stacking direction. That is, a width of the first light-emitting structure 10 may be the smallest among widths of the light-emitting structures, and a width of the third light-emitting structure 30 may be the largest among widths of the light-emitting structures. According to this configuration, because light emitted by the first light-emitting structure 10, the second light-emitting structure 20, and the third light-emitting structure 30 may be effectively emitted in the light-emitting direction, light extraction efficiency may be improved.

Each of the first light-emitting structure 10, the second light-emitting structure 20, and the third light-emitting structure 30 may include a first conductivity type semiconductor layer, an active layer, and a second conductivity type semiconductor layer which are stacked. For example, in the present embodiment, each of the first light-emitting structure 10, the second light-emitting structure 20, and the third light-emitting structure 30 may have a structure in which a first conductivity type semiconductor layer, an active layer, and a second conductivity type semiconductor layer are sequentially stacked in the stacking direction. In other words, in each of the first light-emitting structure 10, the second light-emitting structure 20, and the third light-emitting structure 30, the first conductivity type semiconductor layer may be a lowermost layer, the active layer may be stacked on the first conductivity type semiconductor layer, and the second conductivity type semiconductor layer may be stacked on the active layer. Also, in each of the first light-emitting structure 10, the second light-emitting structure 20, and the third light-emitting structure 30, the active layer and the first conductivity type semiconductor layer may have a stepped shape that is concave in the horizontal direction with respect to the second conductivity type semiconductor layer. That is, widths of the active layer and the first conductivity type semiconductor layer may be less than a width of the second conductivity type semiconductor layer. In the present embodiment, the first conductivity type semiconductor layer may be a p-type semiconductor layer, and the second conductivity type semiconductor layer may be an n-type semiconductor layer. However, embodiments of the disclosure are not limited thereto, and the first conductivity type semiconductor layer may be an n-type semiconductor layer, and the second conductivity type semiconductor layer may be a p-type semiconductor layer.

Referring to FIG. 1, the first light-emitting structure 10 may include a first conductivity type semiconductor layer 11, an active layer 12 having a quantum well structure, and a second conductivity type semiconductor layer 13 which are sequentially stacked in the stacking direction. The first conductivity type semiconductor layer 11 may be a semiconductor layer doped with first conductivity type impurities (p-type impurities) such as, for example, a p-GaN layer. Examples of the p-type impurities may include Mg, Zn, and Be. The active layer 12 may be a layer that emits light due to recombination of electrons and holes. The active layer 12 may be formed by being grown on the first conductivity type semiconductor layer 11. The active layer 12 may have a quantum well structure. For example, the active layer 12 may have a single quantum well structure or multi-quantum well structure made by periodically changing x, y, and z values in AlₓGa_{y}In_{z}N to adjust a bandgap. For example, a quantum well layer and a barrier layer may be paired in the form of InGaN/GaN, InGaN/InGaN, InGaN/AlGaN, or InGaN/InAlGaN to form a quantum well structure, and bandgap energy may be controlled according to a composition ratio of indium (In) of a material layer including indium (In) to adjust an emission wavelength band. The second conductivity type semiconductor layer 13 may be formed on the active layer 12. The second conductivity type semiconductor layer 13 may be a semiconductor layer doped with second conductivity type impurities (n-type impurities) such as, for example, an n-GaN layer. Examples of the n-type impurities may include Si, Ge, Se, and Te. The active layer 12 and the first conductivity type semiconductor layer 11 may have a stepped shape that is concave in the horizontal direction with respect to the second conductivity type semiconductor layer 13. That is, widths of the active layer 12 and the first conductivity type semiconductor layer 11 may be less than a width of the second conductivity type semiconductor layer 13.

The second light-emitting structure 20 may include a first conductivity type semiconductor layer 21, an active layer 22 having a quantum well structure, and a second conductivity type semiconductor layer 23 which are sequentially stacked. The description of the first conductivity type semiconductor layer 11, the active layer 12, and the second conductivity type semiconductor layer 13 of the first light-emitting structure 10 may apply to the first conductivity type semiconductor layer 21, the active layer 22, and the second conductivity type semiconductor layer 23 of the second light-emitting structure 20. The active layer 22 and the first conductivity type semiconductor layer 21 may have a stepped shape that is concave in the horizontal direction with respect to the second conductivity type semiconductor layer 23. That is, widths of the active layer 22 and the first conductivity type semiconductor layer 21 may be less than a width of the second conductivity type semiconductor layer 23. Widths of the active layer 22 and the first conductivity type semiconductor layer 21 may be greater than a width of the second conductivity type semiconductor layer 13 of the first light-emitting structure 10.

The third light-emitting structure 30 may include a first conductivity type semiconductor layer 31, an active layer 32 having a quantum well structure, and a second conductivity type semiconductor layer 33 which are sequentially stacked. The description of the first conductivity type semiconductor layer 11, the active layer 12, and the second conductivity type semiconductor layer 13 of the first light-emitting structure 10 may apply to the first conductivity type semiconductor layer 31, the active layer 32, and the second conductivity type semiconductor layer 33 of the third light-emitting structure 30. The active layer 32 and the first conductivity type semiconductor layer 31 may have a stepped shape that is concave in the horizontal direction with respect to the second conductivity type semiconductor layer 33. That is, widths of the active layer 32 and the first conductivity type semiconductor layer 31 may be less than a width of the second conductivity type semiconductor layer 33. Widths of the active layer 32 and the first conductivity type semiconductor layer 31 may be greater than a width of the second conductivity type semiconductor layer 23 of the second light-emitting structure 20.

The first light-emitting structure 10, the second light-emitting structure 20, and the third light-emitting structure 30 may be sequentially epitaxially grown and stacked to form the light-emitting portion 100. However, embodiments of the disclosure are not limited thereto, and the first light-emitting structure 10, the second light-emitting structure 20, and the third light-emitting structure 30 may be individually grown on different substrates and then sequentially transferred and stacked to form the light-emitting portion 100.

A second common electrode 40 may be provided and may be an electrode common to the second conductivity type semiconductor layers 13, 23, and 33 of the first light-emitting structure 10, the second light-emitting structure 20, and the third light-emitting structure 30. The second common electrode 40 may be electrically connected to (e.g., contact) the second conductivity type semiconductor layers 13, 23, and 33 of the first light-emitting structure 10, the second light-emitting structure 20, and the third light-emitting structure 30. In a case where the second conductivity type semiconductor layers 13, 23, and 33 are n-type semiconductor layers, the second common electrode 40 may be referred to as an n-common electrode.

The second common electrode 40 may include a second common portion 49 disposed under the light-emitting portion 100, and a plurality of second electrode portions (e.g., second electrode portions 41, 42, and 43) extending from the second common portion 49. For example, a passivation layer 80 may be provided on a bottom surface of the light-emitting portion 100, that is, on a bottom surface of the first light-emitting structure 10, and the second common portion 49 may be provided on a bottom surface of the passivation layer 80. The second electrode portions 41, 42, and 43 may extend from the second common portion 49 and respectively contact side surfaces 13S, 23S, and 33S of the second conductivity type semiconductor layers 13, 23, and 33 of the first light-emitting structure 10, the second light-emitting structure 20, and the third light-emitting structure 30. The second electrode portions 41, 42, and 43 may extend in the stacking direction along a side portion of the light-emitting portion 100. The second electrode portions 41, 42, and 43 may be arranged on the side portion of the light-emitting portion 100 to be spaced apart from each other in the horizontal direction orthogonal to the stacking direction. For example, the second electrode portion 41 may be located at an innermost position, the second electrode portion 42 may be disposed outside the second electrode portion 41, and the second electrode portion 43 may be disposed outside the second electrode portion 42. The second electrode portions 41, 42, and 43 may at least partially surround the side portion of the light-emitting portion 100. In other words, the second electrode portions 41, 42, and 43 may entirely surround the side portion of the light-emitting portion 100, or may partially surround the side portion of the light-emitting portion 100. In the present embodiment, the second electrode portions 41, 42, and 43 may entirely surround the side portion of the light-emitting portion 100. When the second electrode portions 41, 42, and 43 entirely surround the side portion of the light-emitting portion 100, it means that, when the light-emitting portion 100 is viewed from above to below, each of the second electrode portions 41, 42, and 43 is in the shape of a closed band. The second common electrode 40 may include an electrode material. The electrode material may include, for example, Al, Ti, Pt, Ag, Au, Pd, TiW, or any of various combinations thereof. The second common electrode 40 may include a reflective electrode material such as, for example, Al or Ag. Alternatively, the second common electrode 40 may include a transparent electrode material. The transparent electrode material may include, for example, indium tin oxide (ITO).

The light-emitting device 1 according to an embodiment may further include a passivation structure for insulation between the second common electrode 40 and side surfaces of the first conductivity type semiconductor layers 11, 21, and 31 and the active layers 12, 22, and 32 of the first light-emitting structure 10, the second light-emitting structure 20, and the third light-emitting structure 30, and for insulation between the second electrode portions 41, 42, and 43. The passivation structure may include a separation layer 50 and a protective layer 60.

The separation layer 50 may separate (e.g., insulate) the side surfaces of the first conductivity type semiconductor layers 11, 21, and 31 and the active layers 12, 22, and 32 of the first light-emitting structure 10, the second light-emitting structure 20, and the third light-emitting structure 30 from the second common electrode 40 (e.g., the second electrode portions 41, 42, and 43). The separation layer 50 may include a plurality of separation layers 51, 52, and 53. The plurality of separation layers 51, 52, and 53 may partially extend beyond active layers of corresponding light-emitting structures to second conductivity type semiconductor layers of the corresponding light-emitting structures. Accordingly, the side surfaces of the first conductivity type semiconductor layers 11, 21, and 31 and the active layers 12, 22, and 32 of the first light-emitting structure 10, the second light-emitting structure 20, and the third light-emitting structure 30 may be stably separated (e.g., insulated) from the second electrode portions 41, 42, and 43.

For example, the separation layer 51 may be disposed between the second electrode portion 41 and the side surfaces of the first conductivity type semiconductor layer 11 and the active layer 12 of the first light-emitting structure 10. The separation layer 51 may partially extend to the second conductivity type semiconductor layer 13 of the first light-emitting structure 10 beyond the active layer 12 of the first light-emitting structure 10. In other words, the separation layer 51 may be partially inserted into the second conductivity type semiconductor layer 13 of the first light-emitting structure 10. The separation layer 52 may be disposed between the second electrode portion 42 and the side surfaces of the first conductivity type semiconductor layer 21 and the active layer 22 of the second light-emitting structure 20. The separation layer 52 may partially extend to the second conductivity type semiconductor layer 23 of the second light-emitting structure 20 beyond the active layer 22 of the second light-emitting structure 20. In other words, the separation layer 52 may be partially inserted into the second conductivity type semiconductor layer 23 of the second light-emitting structure 20. The separation layer 53 may be disposed between the second electrode portion 43 and the side surfaces of the first conductivity type semiconductor layer 31 and the active layer 32 of the third light-emitting structure 30. The separation layer 53 may partially extend to the second conductivity type semiconductor layer 33 of the third light-emitting structure 30 beyond the active layer 32 of the third light-emitting structure 30. In other words, the separation layer 53 may be partially inserted into the second conductivity type semiconductor layer 33 of the third light-emitting structure 30.

A material of the separation layer 50 is not particularly limited. For example, the separation layer 50 may include a dielectric material. The dielectric material may include SiO₂, TiO₂, Si₃N₄, AlOₓ, AlOₓN_{y}, Ta₂O₅, TiN, AlN, ZrO₂, TiAlN, TiSiN, HfOₓ, ZAZ, or any of various combinations thereof. A thickness of the separation layer 50 is not particularly limited, and may be, for example, about 1 nm to about 300 nm. The separation layer 50 may restore side surfaces of the first light-emitting structure 10, the second light-emitting structure 20, and the third light-emitting structure 30 damaged by an etching process described below. Also, materials suitable for the first light-emitting structure 10, the second light-emitting structure 20, and the third light-emitting structure 30 may be selected as the separation layers 51, 52, and 53.

The protective layer 60 may insulate the second electrode portions 41, 42, and 43 from each other. The protective layer 60 may include protective layers 61 and 62. The protective layer 61 may be disposed between the second electrode portion 41 and the second electrode portion 42, and the protective layer 62 may be disposed between the second electrode portion 42 and the second electrode portion 43. The protective layer 60 may protect the second electrode portions 41 and 42 formed first in a process of sequentially forming the second electrode portions 41, 42, and 43 described below. A material of the protective layer 60 is not particularly limited. For example, the protective layer 60 may include a dielectric material. The dielectric material may include SiO₂, TiO₂, Si₃N₄, AlOₓ, AlOₓN_{y}, Ta₂O₅, TiN, AlN, ZrO₂, TiAlN, TiSiN, HfOₓ, ZAZ, or any of various combinations thereof. The protective layer 60 may be formed of the same material as a material used to form the separation layer 50. The protective layer 60 may be formed of a different material from the material used to form the separation layer 50.

A first common electrode 70 may be provided and may be an electrode common to the first conductivity type semiconductor layers 11, 21, and 31 of the first light-emitting structure 10, the second light-emitting structure 20, and the third light-emitting structure 30. The first common electrode 70 may be electrically connected to (e.g., contact) the first conductivity type semiconductor layers 11, 21, and 31 of the first light-emitting structure 10, the second light-emitting structure 20, and the third light-emitting structure 30. In a case where the first conductivity type semiconductor layers 11, 21, and 31 are p-type semiconductor layers, the first common electrode 70 may be referred to as a p-common electrode.

The first common electrode 70 may include a first common portion 79 disposed under the light-emitting portion 100, and a plurality of first electrode portions (e.g., first electrode portions 71, 72, and 73) extending from the first common portion 79. At least one of the first electrode portions 71, 72, and 73 may have a conductive via structure The first electrode portions 71, 72, and 73 may respectively contact the first conductivity type semiconductor layers 11, 21, and 31 of the first light-emitting structure 10, the second light-emitting structure 20, and the third light-emitting structure 30. The first electrode portion 71 may pass through the passivation layer 80 to contact a bottom surface of the first conductivity type semiconductor layer 11 of the first light-emitting structure 10. The first electrode portion 71 may be partially inserted into the first conductivity type semiconductor layer 11 of the first light-emitting structure 10. The first electrode portions 72 and 73 may have conductive via structures. The first electrode portion 72 may pass through the first light-emitting structure 10 from a bottom surface of the passivation layer 80 and electrically contact the first conductivity type semiconductor layer 21 of the second light-emitting structure 20. The first electrode portion 72 may be partially inserted into the first conductivity type semiconductor layer 21 of the second light-emitting structure 20. A passivation element 72x may insulate the first electrode portion 72 from the first light-emitting structure 10. The first electrode portion 73 may pass through the first light-emitting structure 10 and the second light-emitting structure 20 from the bottom surface of the passivation layer 80 and electrically contact the first conductivity type semiconductor layer 31 of the third light-emitting structure 30. The first electrode portion 73 may be partially inserted into the first conductivity type semiconductor layer 31 of the third light-emitting structure 30. A passivation element 73x may insulate the first electrode portion 73 from the first light-emitting structure 10 and the second light-emitting structure 20. The passivation elements 72x and 73x may include a dielectric material. The dielectric material may include SiO₂, TiO₂, Si₃N₄, AlOₓ, AlOₓN_{y}, Ta₂O₅, TiN, AlN, ZrO₂, TiAlN, TiSiN, HfOₓ, ZAZ, or any of various combinations thereof. The first common electrode 70 may include an electrode material. The electrode material may include, for example, Al, Ti, Pt, Ag, Au, Pd, TiW, or any of various combinations thereof. Alternatively, the first common electrode 70 may include a transparent electrode material. The transparent electrode material may include, for example, ITO. The first common electrode 70 may include a reflective electrode material such as, for example, Al or Ag.

The light-emitting device 1 may be bonded to a substrate 200 of a display panel. The substrate 200 of the display panel may include bonding pads 201 and 202 respectively corresponding to the second common portion 49 of the second common electrode 40 and the first common portion 79 of the first common electrode 70. In FIG. 1, the substrate 200 of the display panel is shown separated from the light-emitting device 1.

Technology for applying light-emitting devices (e.g., micro-light-emitting diodes (LEDs)) to displays has been greatly developed, and televisions to which micro-LEDs are applied have begun to be released. Furthermore, attempts have been made to apply micro-LEDs to augmented reality devices. In displays for augmented reality devices, very small micro-LED display chips (or panels) may be monolithically made at a wafer level without a process of transferring micro-LEDs like in television displays. In television displays, the size of one pixel may be several tens to hundreds of micrometers, but, for example, in small or ultra-small displays such as displays for augmented reality devices, the size of one pixel may be very small (e.g., only a few micrometers).

According to comparative embodiments, it may be difficult to obtain a sufficient light output from micro-LEDs with sizes of a few micrometers. Also, for example, in the case of micro-LEDs that emit red light, the luminous efficiency may be low, so a current density may need to be greatly increased to obtain a sufficient light amount. In this case, a high operating voltage may be required. Additionally, the high current density may cause heating, breakdown, etc. As a display's resolution increases, it may become more difficult to obtain a sufficient light amount from micro-LEDs. In other words, as the size of a micro-LED decreases, the resolution increases, but luminous efficiency of the micro-LED may decrease, making it difficult to obtain a sufficient light amount. When the absolute amount of a light amount is insufficient due to a reduction in the size of a micro-LED, a signal-to-noise ratio may be degraded.

Parallel connection of a plurality of micro-LEDs emitting light of the same wavelength may lower the operating voltage and also obtain a sufficient light amount. For example, according to the characteristics of a driving circuit, a voltage of less than 3.5 V may be generally needed to drive low-power micro-LEDs. For example, assuming that the amount of current needed to obtain a sufficient light amount from one micro-LED is 100, a driving voltage for this may be approximately 4.5 V, which may cause a problem of not conforming to the conditions of the driving circuit. In this case, when two micro-LEDs are connected to each other in parallel, the amount of current required for each micro-LED may be 50, and a voltage may be approximately 3.5 V. For example, when three micro-LEDs are connected to each other in parallel, the amount of current required for each micro-LED may be about 33.3, and a voltage may be approximately 3.0V. Therefore, due to the parallel connection of the plurality of micro-LEDs emitting light of the same wavelength, a sufficient light amount may be obtained, and the driving voltage may conform to the conditions of the driving circuit.

An arrangement structure of a plurality of micro-LEDs includes a horizontal arrangement structure and a vertical arrangement structure. In the horizontal arrangement structure, a plurality of micro-LEDs are horizontally arranged, and in the vertical arrangement structure, a plurality of micro-LEDs are vertically stacked in one pixel area (or one subpixel area). For a pixel of a given size, because the horizontal arrangement structure may require micro-LEDs to be manufactured in a smaller size than the vertical arrangement structure, a process difficulty for manufacturing the horizontal arrangement structure may be high. In the vertical arrangement structure, because micro-LEDs are vertically arranged, a process difficulty for manufacturing the vertical arrangement structure may be high. However, in the vertical arrangement structure, micro-LEDs may be manufactured in a larger size than in the horizontal arrangement structure, which may result in greater external quantum efficiency (EQE) than in the horizontal arrangement structure.

In order to form electrodes for driving a plurality of light-emitting structures in a light-emitting device in which the plurality of light-emitting structures emitting light of the same wavelength are vertically arranged, conductive vias that partially or entirely pass through the plurality of light-emitting structures may be used. For example, six electrodes may be used to drive three light-emitting structures, and five among the six electrodes may be implemented by conductive vias. As the number of conductive vias increases, the emission area of the plurality of light-emitting structures may decrease, making it difficult to secure a sufficient light amount. Accordingly, it may be beneficial to reduce the number of conductive vias in order to secure a wide emission area.

In the embodiment of the light-emitting device 1 illustrated in FIG. 1, each of a plurality of light-emitting structures, for example, the first light-emitting structure 10, the second light-emitting structure 20, and the third light-emitting structure 30, may correspond to a micro-LED. According to the light-emitting device 1 of the present embodiment, by vertically stacking a plurality of light-emitting structures that emit light of the same wavelength (e.g., the first light-emitting structure 10, the second light-emitting structure 20, and the third light-emitting structure 30), the first light-emitting structure 10, the second light-emitting structure 20, and the third light-emitting structure 30 may be manufactured in larger sizes than in a horizontal arrangement structure. Therefore, it is possible to implement the light-emitting device 1 having a high efficiency (EQE) relative to the size of a given pixel area. The first light-emitting structure 10, the second light-emitting structure 20, and the third light-emitting structure 30 may be connected to each other in parallel by connecting the first conductivity type semiconductor layers 11, 21, and 31 of a plurality of light-emitting structures (e.g., the first light-emitting structure 10, the second light-emitting structure 20, and the third light-emitting structure 30) to the first common electrode 70 and connecting the second conductivity type semiconductor layers 13, 23, and 33 of the first light-emitting structure 10, the second light-emitting structure 20, and the third light-emitting structure 30 to the second common electrode 40. Accordingly, the light-emitting device 1 capable of obtaining a sufficient light amount with a low driving voltage may be implemented.

The second electrode portions 41, 42, and 43 of the second common electrode 40 may extend from the second common portion 49 disposed under the light-emitting portion 100 and may be disposed on the side portion of the light-emitting portion 100. The first electrode portions 71, 72, and 73 of the first common electrode 70 may be arranged below the light-emitting portion 100, and the first electrode portions 72 and 73 may have conductive via structures. Accordingly, because the number of conductive vias is two and thus the size of the light-emitting device 1, that is, an emission area in a given pixel area (or a subpixel area), may be maximized, an increase in the emission area, an increase in luminous efficiency due to this increase in the emission area, and a decrease in power consumption may be obtained.

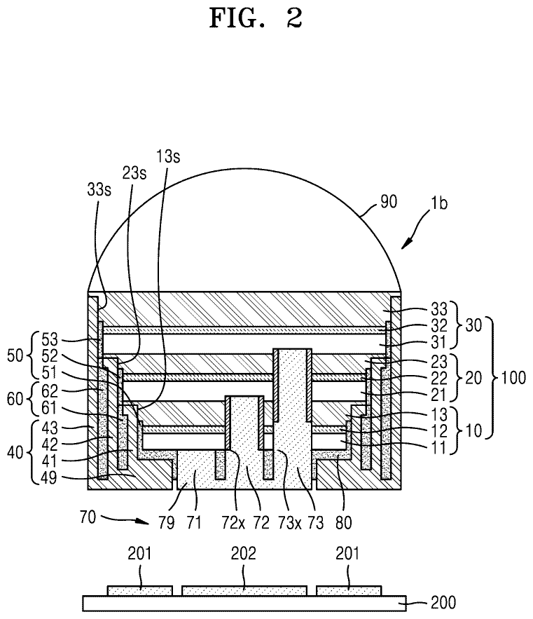

FIG. 2 is a schematic cross-sectional view of a light-emitting device 1b according to an embodiment. The light-emitting device 1b of the present embodiment is different from the light-emitting device 1 of FIG. 1 in that a lens 90 is further provided. Hereinafter, differences therebetween will be focused on and described, and components performing the same function will be indicated by the same reference numeral, and repeated descriptions thereof may be omitted.

Referring to FIG. 2, the light-emitting device 1b may further include the lens 90. The lens 90 may be provided on the light-emitting portion 100, that is, on a light-emitting side of the light-emitting portion 100. The lens 90 may be formed by, for example, thermoforming of a photoresist. The lens 90 may adjust an angle at which light generated from a plurality of light-emitting structures (e.g., the first light-emitting structure 10, the second light-emitting structure 20, and the third light-emitting structure 30) is emitted upward from the light-emitting portion 100. Accordingly, light may be emitted from the light-emitting device 1b in a desired angle range.

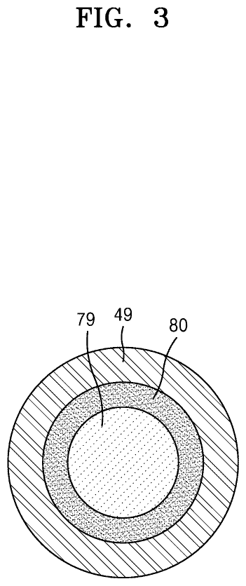

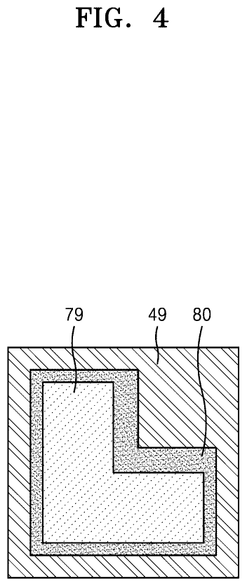

FIGS. 3 and 4 illustrate embodiments of a planar arrangement of the first common portion 79 of the first common electrode 70 and the second common portion 49 of the second common electrode 40. First, referring to FIG. 3, the first common portion 79 of the first common electrode 70 may be arranged inside the second common portion 49 of the second common electrode 40 having a circular shape. Next, referring to FIG. 4, the first common portion 79 of the first common electrode 70 may be arranged inside the second common portion 49 of the second common electrode 40 having a quadrangular shape. The shape of the first common portion 79 is not limited to an “L” shape shown in FIG. 4. The planar arrangement of the first common portion 79 of the first common electrode 70 and the second common portion 49 of the second common electrode 40 is not limited to those shown FIGS. 3 and 4.

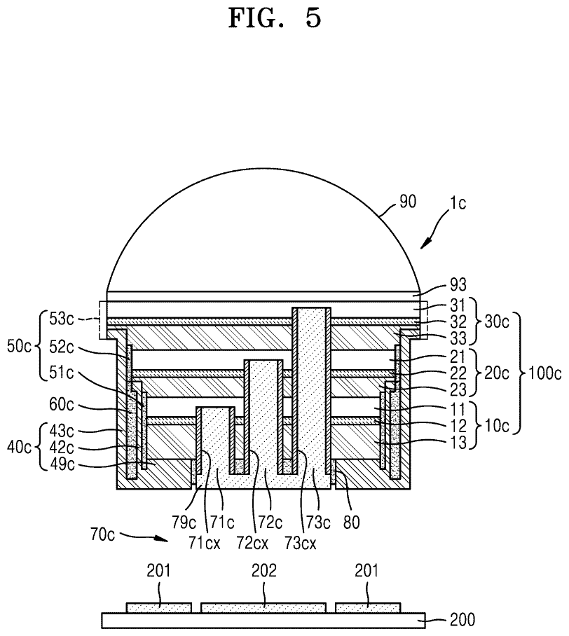

FIG. 5 is a schematic cross-sectional view of a light-emitting device 1c according to an embodiment. The light-emitting device 1c of the present embodiment is different in that each of a plurality of light-emitting structures includes a second conductivity type semiconductor layer, an active layer, and a first conductivity type semiconductor layer which are sequentially stacked in the stacking direction and in shapes of a first common electrode and a second common electrode.

Referring to FIG. 5, the light-emitting device 1c may include a light-emitting portion 100c including a plurality of light-emitting structures that are vertically stacked and emit light of the same wavelength, and a plurality of electrodes for driving the plurality of light-emitting structures. The light-emitting device 1c may correspond to one pixel (or one subpixel) in a display apparatus. Each of the plurality of light-emitting structures may include a second conductivity type semiconductor layer, an active layer having a quantum well structure, and a first conductivity type semiconductor layer which are sequentially stacked in the stacking direction.

The plurality of electrodes may include a first common electrode common to first conductivity type semiconductor layers of the plurality of light-emitting structures, and a second common electrode common to second conductivity type semiconductor layers of the plurality of light-emitting structures. The first common electrode may include a first common portion provided under the light-emitting portion 100c, and a plurality of first electrode portions each extending from the first common portion and respectively contacting the first conductivity type semiconductor layers of the plurality of light-emitting structures. The plurality of first electrode portions may have conductive via structures. The second common electrode may include a second common portion disposed under the light-emitting portion 100c, and a plurality of second electrode portions each extending from the second common portion in the stacking direction. One of the plurality of second electrode portions may be provided under the light-emitting portion 100c and contact a bottom surface of the second conductivity type semiconductor layer of a light-emitting structure located at a lowest position among the plurality of light-emitting structures, and thus, the second common portion may also function as one of the plurality of second electrode portions. The remaining ones of the plurality of second electrode portions may be arranged on a side portion of the light-emitting portion 100c to be spaced apart from each other in the horizontal direction orthogonal to the stacking direction, and respectively contact side surfaces of the second conductivity type semiconductor layers of second or higher-numbered light-emitting structures among the plurality of light-emitting structures. The remaining ones of the plurality of second electrode portions may partially or entirely surround the side portion of the light-emitting portion 100c.

The light-emitting portion 100c may be formed of a Group III-V nitride semiconductor material. Examples of the Group III-V nitride semiconductor material may include GaN, InGaN, AlInGaN, and AlGaInP. For example, the light-emitting portion 100c may be formed of a GaN-based semiconductor material. In the active layer of each of the plurality of light-emitting structures, bandgap energy may be controlled according to a composition ratio of indium (In) in a material layer including indium (In) to determine an emission wavelength band.

In the present embodiment, the light-emitting portion 100c may include a first light-emitting structure 10c, a second light-emitting structure 20c, and a third light-emitting structure 30c that are sequentially stacked. However, embodiments of the disclosure are not limited thereto, and the light-emitting portion 100c may include two or four or more light-emitting structures. In the present embodiment, the first light-emitting structure 10c, the second light-emitting structure 20c, and the third light-emitting structure 30c may emit red light (e.g., light in a wavelength range of 630±20 nm). However, embodiments of the disclosure are not limited thereto, and the first light-emitting structure 10c, the second light-emitting structure 20c, and the third light-emitting structure 30c may emit light of a wavelength band other than red light. For example, the first light-emitting structure 10c, the second light-emitting structure 20c, and the third light-emitting structure 30c may emit green light (e.g., light in a wavelength range of 530±20 nm) or blue light (e.g., light in a wavelength range of 460±20 nm).

The first light-emitting structure 10c may form a lowermost light-emitting structure of the light-emitting portion 100c. The second light-emitting structure 20c may be stacked on the first light-emitting structure 10c, and the third light-emitting structure 30c may be stacked on the second light-emitting structure 20c. The third light-emitting structure 30c may form an uppermost light-emitting structure of the light-emitting portion 100c. The stacking direction of the first light-emitting structure 10c, the second light-emitting structure 20c, and the third light-emitting structure 30c may be the same as the light-emitting direction. The light-emitting portion 100c according to an embodiment may have a shape (e.g., a stepped shape) whose width increases in the stacking direction. That is, a width of the first light-emitting structure 10c may be the smallest among widths of the light-emitting structures, and a width of the third light-emitting structure 30c may be the largest among widths of the light-emitting structures. According to this configuration, because light emitted by the first light-emitting structure 10c, the second light-emitting structure 20c, and the third light-emitting structure 30c may be effectively emitted in the light-emitting direction, light extraction efficiency may be improved.

Each of the first light-emitting structure 10c, the second light-emitting structure 20c, and the third light-emitting structure 30c may include a second conductivity type semiconductor layer, an active layer, and a first conductivity type semiconductor layer which are stacked in the stacking direction. In other words, in each of the first light-emitting structure 10c, the second light-emitting structure 20c, and the third light-emitting structure 30c, the second conductivity type semiconductor layer may be a lowermost layer, the active layer may be stacked on the second conductivity type semiconductor layer, and the first conductivity type semiconductor layer may be stacked on the active layer. In a first light-emitting structure in the stacking direction among the plurality of light-emitting structures (e.g., in the first light-emitting structure 10c), widths of the second conductivity type semiconductor layer, the active layer, and the first conductivity type semiconductor layer may be the same as each other. In each of second or higher-numbered light-emitting structures in the stacking direction among the plurality of light-emitting structures (e.g., in each of the second light-emitting structure 20c and the third light-emitting structure 30c), the second conductivity type semiconductor layer may have a stepped shape that is concave in the horizontal direction with respect to the active layer and the first conductivity type semiconductor layer. That is, in the second or higher-numbered light-emitting structures in the stacking direction among the plurality of light-emitting structures, a width of the second conductivity type semiconductor layer may be less than widths of the active layer and the first conductivity type semiconductor layer.

Referring to FIG. 5, the first light-emitting structure 10c may include a second conductivity type semiconductor layer 13, an active layer 12 having a quantum well structure, and a first conductivity type semiconductor layer 11 which are sequentially stacked in the stacking direction. The second conductivity type semiconductor layer 13 may be a semiconductor layer doped with n-type impurities, for example, an n-GaN layer. Examples of the n-type impurities may include Si, Ge, Se, and Te. The active layer 12 may be a layer that emits light due to recombination of electrons and holes. The active layer 12 may be formed by being grown on the second conductivity type semiconductor layer 13. The active layer 12 may have a quantum well structure. For example, the active layer 12 may have a single quantum well structure or multi-quantum well structure made by periodically changing x, y, and z values in AlₓGa_{y}In_{z}N to adjust a bandgap. For example, a quantum well layer and a barrier layer may be paired in the form of InGaN/GaN, InGaN/InGaN, InGaN/AlGaN, or InGaN/InAlGaN to form a quantum well structure, and bandgap energy may be controlled according to a composition ratio of indium (In) of a material layer including indium (In) to adjust an emission wavelength band. The first conductivity type semiconductor layer 11 may be grown on the active layer 12. The first conductivity type semiconductor layer 11 may be a semiconductor layer doped with p-type impurities, for example, a p-GaN layer. Examples of the p-type impurities may include Mg, Zn, and Be. In the first light-emitting structure 10c, the widths of the second conductivity type semiconductor layer 13, the active layer 12, and the first conductivity type semiconductor layer 11 may be the same as each other.

The second light-emitting structure 20c may include a second conductivity type semiconductor layer 23, an active layer 22 having a quantum well structure, and a first conductivity type semiconductor layer 21 which are sequentially stacked. The description of the second conductivity type semiconductor layer 13, the active layer 12, and the first conductivity type semiconductor layer 11 of the first light-emitting structure 10c may apply to the second conductivity type semiconductor layer 23, the active layer 22, and the first conductivity type semiconductor layer 21 of the second light-emitting structure 20c. However, in the second light-emitting structure 20c, the second conductivity type semiconductor layer 23 may have a stepped shape that is concave in the horizontal direction with respect to the active layer 22 and the first conductivity type semiconductor layer 21. That is, a width of the second conductivity type semiconductor layer 23 may be less than widths of the active layer 22 and the first conductivity type semiconductor layer 21. The width of the second conductivity type semiconductor layer 23 may be greater than the width of the first conductivity type semiconductor layer 11 of the first light-emitting structure 10c.

The third light-emitting structure 30c may include a second conductivity type semiconductor layer 33, an active layer 32 having a quantum well structure, and a first conductivity type semiconductor layer 31 which are sequentially stacked. The description of the second conductivity type semiconductor layer 13, the active layer 12, and the first conductivity type semiconductor layer 11 of the first light-emitting structure 10c may apply to the second conductivity type semiconductor layer 33, the active layer 32, and the first conductivity type semiconductor layer 31 of the third light-emitting structure 30c. However, in the third light-emitting structure 30c, the second conductivity type semiconductor layer 33 may have a stepped shape that is concave in the horizontal direction with respect to the active layer 32 and the first conductivity type semiconductor layer 31. That is, a width of the second conductivity type semiconductor layer 33 may be less than widths of the active layer 32 and the first conductivity type semiconductor layer 31. The width of the second conductivity type semiconductor layer 33 may be greater than the width of the first conductivity type semiconductor layer 21 of the second light-emitting structure 20c.

The first light-emitting structure 10c, the second light-emitting structure 20c, and the third light-emitting structure 30c may be sequentially epitaxially grown and stacked to form the light-emitting portion 100c. However, embodiments of the disclosure are not limited thereto, and the first light-emitting structure 10c, the second light-emitting structure 20c, and the third light-emitting structure 30c may be individually grown on different substrates and then sequentially transferred and stacked to form the light-emitting portion 100c.

The second common electrode 40c may be an electrode common to the second conductivity type semiconductor layers 13, 23, and 33 of the first light-emitting structure 10c, the second light-emitting structure 20c, and the third light-emitting structure 30c. The second common electrode 40c may be electrically connected to (e.g., contact) the second conductivity type semiconductor layers 13, 23, and 33 of the first light-emitting structure 10c, the second light-emitting structure 20c, and the third light-emitting structure 30c. In a case where the second conductivity type semiconductor layers 13, 23, and 33 are n-type semiconductor layers, the second common electrode 40c may be referred to as an n-common electrode.

The second common electrode 40c may include a second common portion 49c disposed under the light-emitting portion 100c, and a plurality of second electrode portions (e.g., second electrode portions 42c and 43c) extending from the second common portion 49c. In the present embodiment, the second common portion 49c may function as the second electrode portion 41 in the embodiment of FIG. 1. To this end, the second common portion 49c may contact a bottom surface of the second conductivity type semiconductor layer 13 of the light-emitting structure located at the lowest position among the plurality of light-emitting structures, namely, the first light-emitting structure 10c. The second electrode portions 42c and 43c may extend from the second common portion 49c and respectively contact the side surfaces of the second conductivity type semiconductor layers 23 and 33 of their corresponding light-emitting structures among the second or higher-numbered light-emitting structures from among the plurality of light-emitting structures (e.g., the second light-emitting structure 20c and the third light-emitting structure 30c). The second electrode portions 42c and 43c may each extend in the stacking direction along the side portion of the light-emitting portion 100c, and may be arranged to be spaced apart from each other in the horizontal direction. For example, the second electrode portion 42c may be located at an innermost position, and the second electrode portion 43c may be disposed outside the second electrode portion 42c. The second electrode portions 42c and 43c may at least partially surround the side portion of the light-emitting portion 100c. In other words, the second electrode portions 42c and 43c may entirely surround the side portion of the light-emitting portion 100c, or may partially surround the side portion of the light-emitting portion 100c. In the present embodiment, the second electrode portions 42c and 43c entirely surround the side portion of the light-emitting portion 100c. The second common electrode 40c may include an electrode material. The electrode material may include, for example, Al, Ti, Pt, Ag, Au, Pd, TiW, or any of various combinations thereof. The second common electrode 40c may include a reflective electrode material such as, for example, Al or Ag. Alternatively, the second common electrode 40c may include a transparent electrode material. The transparent electrode material may include, for example, ITO.

The light-emitting device 1c according to an embodiment may further include a passivation structure for insulation between the second common electrode 40c and side surfaces of the first conductivity type semiconductor layer 11, the active layer 12, and the second conductivity type semiconductor layer 13 of the first light-emitting structure 10c and the first conductivity type semiconductor layer 21 and the active layer 22 of the second light-emitting structure 20c and insulation between the second electrode portions 42c and 43c. The passivation structure may include a separation layer 50c and a protective layer 60c.

The separation layer 50c may separate (e.g., insulates) the side surfaces of the first conductivity type semiconductor layer 11, the active layer 12, and the second conductivity type semiconductor layer 13 of the first light-emitting structure 10c and the first conductivity type semiconductor layer 21 and the active layer 22 of the second light-emitting structure 20c from the second common electrode 40c (e.g., the second electrode portions 42c and 43c). The separation layer 50c may include a plurality of separation layers 51c and 52c. Each of the plurality of separation layers may be disposed between a corresponding second electrode portion among the plurality of second electrode portions and side surfaces of a first conductivity type semiconductor layer, an active layer, and a second conductivity type semiconductor layer of a light-emitting structure located under a light-emitting structure corresponding to the corresponding second electrode portion among the plurality of light-emitting structures. Each of the plurality of separation layers 51c and 52c may partially extend beyond a first conductivity type semiconductor layer of a light-emitting structure located under a corresponding light-emitting structure to a second conductivity type semiconductor layer of the corresponding light-emitting structure. For example, the separation layer 51c may be disposed between the second electrode portion 42c and the side surfaces of the first conductivity type semiconductor layer 11, the active layer 12, and the second conductivity type semiconductor layer 13 of the first light-emitting structure 10c. The separation layer 51c may partially extend to the second conductivity type semiconductor layer 23 of the second light-emitting structure 20c beyond the first conductivity type semiconductor layer 11 of the first light-emitting structure 10c. The separation layer 52c may be disposed between the second electrode portion 43c and the side surfaces of the first conductivity type semiconductor layer 21 and the active layer 22 of the second light-emitting structure 20c. The separation layer 52c may partially extend to the second conductivity type semiconductor layer 33 of the third light-emitting structure 30c beyond the first conductivity type semiconductor layer 21 of the second light-emitting structure 20c. The separation layer 50c may further include a separation layer 53c covering the side surfaces of the active layer 32 and the first conductivity type semiconductor layer 31 of the third light-emitting structure 30c. A material of the separation layer 50c is not particularly limited. For example, the separation layer 50c may include a dielectric material. The dielectric material may include SiO₂, TiO₂, Si₃N₄, AlOₓ, AlOₓN_{y}, Ta₂O₅, TiN, AlN, ZrO₂, TiAlN, TiSiN, HfOₓ, ZAZ, or any of various combinations thereof. A thickness of the separation layer 50c is not particularly limited, and may be, for example, about 1 nm to about 300 nm. The separation layer 50c may restore side surfaces of the first light-emitting structure 10c and the second light-emitting structure 20c damaged by an etching process described below. Materials suitable for the first light-emitting structure 10c, the second light-emitting structure 20c, and the third light-emitting structure 30c may be selected as the separation layers 51c, 52c, and 53c.

The protective layer 60c may insulate the second electrode portions 42c and 43c from each other. The protective layer 60c may be disposed between the second electrode portions 42c and 43c. The protective layer 60c may protect the second electrode portion 42c formed first in a process of sequentially forming the second electrode portions 42c and 43c, which is to be described below. A material of the protective layer 60c is not particularly limited. For example, the protective layer 60c may include a dielectric material. The dielectric material may include SiO₂, TiO₂, Si₃N₄, AlOₓ, AlOₓN_{y}, Ta₂O₅, TiN, AlN, ZrO₂, TiAlN, TiSiN, HfOₓ, ZAZ, or any of various combinations thereof. The separation layer 50c and the protective layer 60c may be formed of the same material as each other or may be formed of different materials from each other.

A first common electrode 70c may be provided and may be an electrode common to the first conductivity type semiconductor layers 11, 21, and 31 of the first light-emitting structure 10c, the second light-emitting structure 20c, and the third light-emitting structure 30c. The first common electrode 70c may be electrically connected to (e.g., contact) the first conductivity type semiconductor layers 11, 21, and 31 of the first light-emitting structure 10c, the second light-emitting structure 20c, and the third light-emitting structure 30c. In a case where the first conductivity type semiconductor layers 11, 21, and 31 are p-type semiconductor layers, the first common electrode 70c may be referred to as a p-common electrode.

The first common electrode 70c may include a first common portion 79c disposed under the light-emitting portion 100c, and a plurality of first electrode portions (e.g., first electrode portions 71c, 72c, and 73c) extending from the first common portion 79c. The first electrode portions 71c, 72c, and 73c may have conductive via structures. The first electrode portion 71c may pass through the passivation layer 80 and the second conductivity type semiconductor layer 13 and the active layer 12 of the first light-emitting structure 10c and contact the first conductivity type semiconductor layer 11. A passivation element 71cx may insulate the first electrode portion 71c from the second conductivity type semiconductor layer 13 and the active layer 12 of the first light-emitting structure 10c. The first electrode portion 72c may pass through the passivation layer 80, the first light-emitting structure 10c, and the second conductivity type semiconductor layer 23 and the active layer 22 of the second light-emitting structure 20c and electrically contact the first conductivity type semiconductor layer 21. A passivation element 72cx may insulate the first electrode portion 72c from the first light-emitting structure 10c and the second conductivity type semiconductor layer 23 and the active layer 22 of the second light-emitting structure 20c. The first electrode portion 73c may pass through the passivation layer 80, the first light-emitting structure 10c, the second light-emitting structure 20c, and the second conductivity type semiconductor layer 33 and the active layer 32 of the third light-emitting structure 30c and electrically contact the first conductivity type semiconductor layer 31. A passivation element 73cx may insulate the first electrode portion 73c from the first light-emitting structure 10c, the second light-emitting structure 20c, and the second conductivity type semiconductor layer 33 and the active layer 32 of the third light-emitting structure 30c. The passivation elements 71cx, 72cx, and 73cx may include a dielectric material. The dielectric material may include SiO₂, TiO₂, Si₃N₄, AlOₓ, AlOₓN_{y}, Ta₂O₅, TiN, AlN, ZrO₂, TiAlN, TiSiN, HfOₓ, ZAZ, or any of various combinations thereof. p-electrodes may include an electrode material. The electrode material may include, for example, Al, Ti, Pt, Ag, Au, Pd, TiW, or any of various combinations thereof. The first common electrode 70c may include an electrode material. The electrode material may include, for example, Al, Ti, Pt, Ag, Au, Pd, TiW, or any of various combinations thereof. The first common electrode 70c may include a reflective electrode material such as, for example, Al or Ag. Alternatively, the first common electrode 70c may include a transparent electrode material. The transparent electrode material may include, for example, ITO.

The light-emitting device 1c may be bonded to the substrate 200 of the display panel. The substrate 200 of the display panel may include bonding pads 201 and 202 respectively corresponding to the second common portion 49c of the second common electrode 40c and the first common portion 79c of the first common electrode 70c. In FIG. 5, the substrate 200 of the display panel is shown separated from the light-emitting device 1c.

Referring to FIG. 5, the light-emitting device 1c may further include the lens 90. The lens 90 may be provided on the light-emitting portion 100c, that is, on a light-emitting side of the light-emitting portion 100c. A passivation layer 93 may be provided on the light-emitting portion 100c, and the lens 90 may be provided on the passivation layer 93. The lens 90 may be formed by, for example, thermoforming of a photoresist. The lens 90 may adjust an angle at which light generated from the first light-emitting structure 10c, the second light-emitting structure 20c, and the third light-emitting structure 30c is emitted upward from the light-emitting portion 100c. Accordingly, light may be emitted from the light-emitting device 1c in a desired angle range.

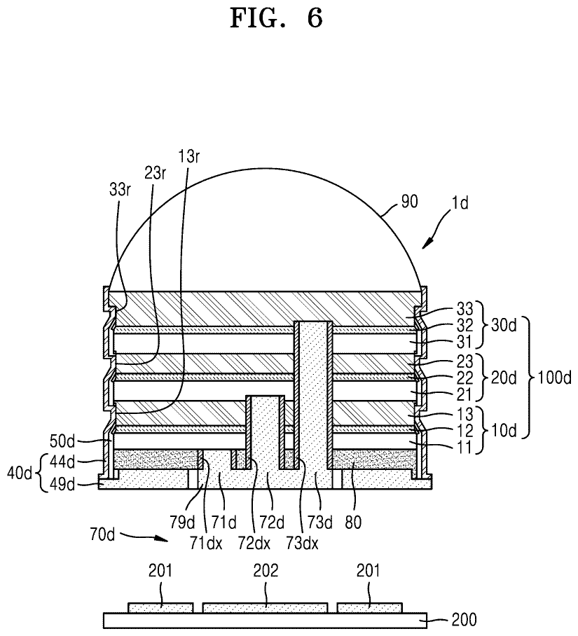

FIG. 6 is a schematic cross-sectional view of a light-emitting device 1d according to an embodiment. Referring to FIG. 6, the light-emitting device 1d according to an embodiment may include a light-emitting portion 100d, a second common electrode 40d, a separation layer 50d, and a first common electrode 70d.

The light-emitting portion 100d may include a first light-emitting structure 10d, a second light-emitting structure 20d, and a third light-emitting structure 30d that are sequentially stacked and emit light beams of the same wavelength. The descriptions of the first light-emitting structure 10, the second light-emitting structure 20, and the third light-emitting structure 30 of FIG. 1 may apply to the first light-emitting structure 10d, the second light-emitting structure 20d, and the third light-emitting structure 30d, respectively. However, the light-emitting portion 100d of the present embodiment is different from the light-emitting portion 100 of FIG. 1 in that a side surface thereof is substantially parallel to the stacking direction. In other words, a width of the light-emitting portion 100d of the present embodiment is almost uniform in the stacking direction, except for concave portions 13r, 23r, and 33r described later.

A side surface of a second conductivity type semiconductor layer of each of the first light-emitting structure 10d, the second light-emitting structure 20d, and the third light-emitting structure 30d may include a concave portion having a stepped shape that is concave with respect to side surfaces of an active layer and a first conductivity type semiconductor layer of each of the first light-emitting structure 10d, the second light-emitting structure 20d, and the third light-emitting structure 30d. For example, a side surface of a second conductivity type semiconductor layer 13 of the first light-emitting structure 10d may include a concave portion 13r that is concave with respect to side surfaces of an active layer 12 and a first conductivity type semiconductor layer 11 thereof. A side surface of a second conductivity type semiconductor layer 23 of the second light-emitting structure 20d may include a concave portion 23r that is concave with respect to side surfaces of an active layer 22 and a first conductivity type semiconductor layer 21 thereof. A side surface of a second conductivity type semiconductor layer 33 of the third light-emitting structure 30d may include a concave portion 33r that is concave with respect to side surfaces of an active layer 32 and a first conductivity type semiconductor layer 31 thereof.

The separation layer 50d may cover a side portion of the light-emitting portion 100d. A plurality of openings corresponding to the concave portions 13r, 23r, and 33r provided in the side surfaces of the second conductivity type semiconductor layers 13, 23, and 33 of the first light-emitting structure 10d, the second light-emitting structure 20d, and the third light-emitting structure 30d may be provided in the separation layer 50d, and the concave portions 13r, 23r, and 33r may be exposed at the side portion of the light-emitting portion 100d through the plurality of openings. The separation layer 50d may entirely or partially cover the side portion of the light-emitting portion 100d. A material of the separation layer 50d is not particularly limited. For example, the separation layer 50d may include a dielectric material. The dielectric material may include SiO₂, TiO₂, Si₃N₄, AlOₓ, AlOₓN_{y}, Ta₂O₅, TiN, AlN, ZrO₂, TiAlN, TiSiN, HfOₓ, ZAZ, or any of various combinations thereof. A thickness of the separation layer 50d is not particularly limited.

The second common electrode 40d may contact the side surfaces of the second conductivity type semiconductor layers 13, 23, and 33 of the first light-emitting structure 10d, the second light-emitting structure 20d, and the third light-emitting structure 30d through the concave portions 13r, 23r, and 33r. In an embodiment, the second common electrode 40d may include a second common portion 49d and a second electrode portion 44d extending from the second common portion 49d. The second common portion 49d may be disposed under the light-emitting portion 100d. In an embodiment, the passivation layer 80 may be disposed under the light-emitting portion 100d, and the second common portion 49d may be provided on a bottom surface of the passivation layer 80. The second electrode portion 44d may extend along an outer surface of the separation layer 50d from the second common portion 49d in the stacking direction. The second electrode portion 44d may partially or entirely cover the outer surface of the separation layer 50d. The second electrode portion 44d may contact the side surfaces of the n-type semiconductor layers (e.g., the second conductivity type semiconductor layers) 13, 23, and 33 of the first light-emitting structure 10d, the second light-emitting structure 20d, and the third light-emitting structure 30d through the concave portions 13r, 23r, and 33r. The second common electrode 40d may include an electrode material. The electrode material may include, for example, Al, Ti, Pt, Ag, Au, Pd, TiW, or any of various combinations thereof. The second common electrode 40d may include a reflective electrode material such as, for example, Al or Ag. Alternatively, the second common electrode 40d may include a transparent electrode material. The transparent electrode material may include, for example, ITO.

The first common electrode 70d may be provided with a first common portion 79d and a plurality of first electrode portions (e.g., first electrode portions 71d, 72d, and 73d). The first common portion 79d may be disposed under the light-emitting portion 100d. The first electrode portions 71d, 72d, and 73d may each extend from the first common portion 79d, and respectively contact the first conductivity type semiconductor layers 11, 21, and 31 of the first light-emitting structure 10d, the second light-emitting structure 20d, and the third light-emitting structure 30d. The first electrode portions 71d, 72d, and 73d may have conductive via structures. The first electrode portion 71d may pass through the passivation layer 80 and contact the first conductivity type semiconductor layer 11 of the first light-emitting structure 10d. According to some embodiments, a passivation element 71dx surrounding an outer circumference of the first electrode portion 71d may be provided. The first electrode portion 72d may pass through the passivation layer 80 and the first light-emitting structure 10d and electrically contact the first conductivity type semiconductor layer 21 of the second light-emitting structure 20d. The passivation element 71dx may insulate the first electrode portion 72d from the first light-emitting structure 10d. The first electrode portion 73d may pass through the passivation layer 80, the first light-emitting structure 10d, and the second light-emitting structure 20d and electrically contact the first conductivity type semiconductor layer 31 of the third light-emitting structure 30d. A passivation element 73dx may insulate the first electrode portion 73c from the first light-emitting structure 10d and the second light-emitting structure 20d. The passivation elements 71dx, 72dx, and 73dx may include a dielectric material. The dielectric material may include SiO₂, TiO₂, Si₃N₄, AlOₓ, AlOₓN_{y}, Ta₂O₅, TiN, AlN, ZrO₂, TiAlN, TiSiN, HfOₓ, ZAZ, or any of various combinations thereof. The first common electrode 70d may include an electrode material. The electrode material may include, for example, Al, Ti, Pt, Ag, Au, Pd, TiW, or any of various combinations thereof. Alternatively, the first common electrode 70d may include a transparent electrode material. The transparent electrode material may include, for example, ITO. The first common electrode 70d may include a reflective electrode material such as, for example, Al or Ag.

The light-emitting device 1d may be bonded to the substrate 200 of the display panel. The substrate 200 of the display panel may include bonding pads 201 and 202 respectively corresponding to the second common portion 49d of the second common electrode 40d and the first common portion 79d of the first common electrode 70d. In FIG. 6, the substrate 200 of the display panel is shown separated from the light-emitting device 1d.

Referring to FIG. 6, the light-emitting device 1d may further include the lens 90. The lens 90 may be provided on the light-emitting portion 100d, that is, on a light-emitting side of the light-emitting portion 100d. The lens 90 may be formed by, for example, thermoforming of a photoresist. The lens 90 may adjust an angle at which light generated from the first light-emitting structure 10d, the second light-emitting structure 20d, and the third light-emitting structure 30d is emitted upward from the light-emitting portion 100d. Accordingly, light may be emitted from the light-emitting device 1d in a desired angle range.

Hereinafter, embodiments of a method of manufacturing the light-emitting devices of FIGS. 1, 2, 5, and 6 will be described.

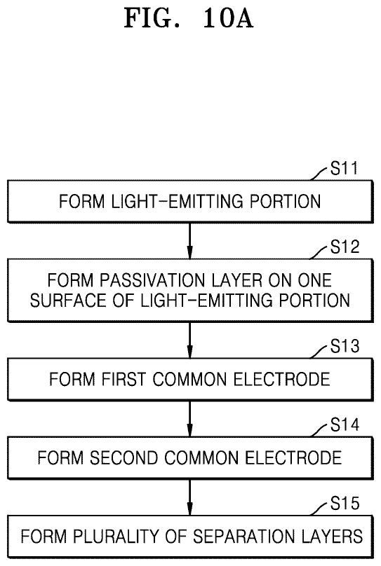

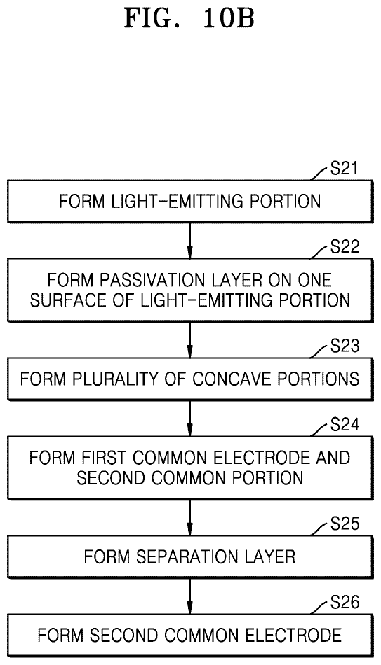

Embodiments of the above-described light-emitting devices may be manufactured using various manufacturing methods. FIG. 10A is a flowchart of an embodiment of a method of manufacturing a light-emitting device. Referring to FIG. 10A, an embodiment of a method of manufacturing a light-emitting device may include an operation S11 of forming a light-emitting portion including a plurality of light-emitting structures, an operation S12 of forming a passivation layer on one surface of the light-emitting portion, an operation S13 of forming a first common electrode including a first common portion on the passivation layer and a plurality of first electrode portions extending from the first common portion and electrically contacting first conductivity type semiconductor layers of the plurality of light-emitting structures, wherein at least one of the first electrode portions has a conductive via structure, an operation S14 of forming a second common electrode including a second common portion on the passivation layer and a plurality of second electrode portions each extending along a side portion of the light-emitting portion from the second common portion to respectively contact side surfaces of second conductivity type semiconductor layers of the plurality of light-emitting structures, and being horizontally spaced apart from each other, and an operation S15 of forming a plurality of separation layers interposed between the plurality of second electrode portions.

The operations S14 and S15 of forming the second common electrode and the plurality of separation layers may be implemented by sequentially performing, with respect to the plurality of light-emitting structures, an operation of exposing side surfaces of a first conductivity type semiconductor layer and an active layer and a surface of a second conductivity type semiconductor layer via etching and depositing a dielectric material on the exposed side surfaces of the first conductivity type semiconductor layer and the active layer and the exposed surface of the second conductivity type semiconductor layer to form a separation layer, an operation of partially etching the separation layer and the second conductivity type semiconductor layer to expose the side surface of the second conductivity type semiconductor layer, and an operation of depositing an electrode material on exposed side surfaces of the separation layer and the second conductivity type semiconductor layer.

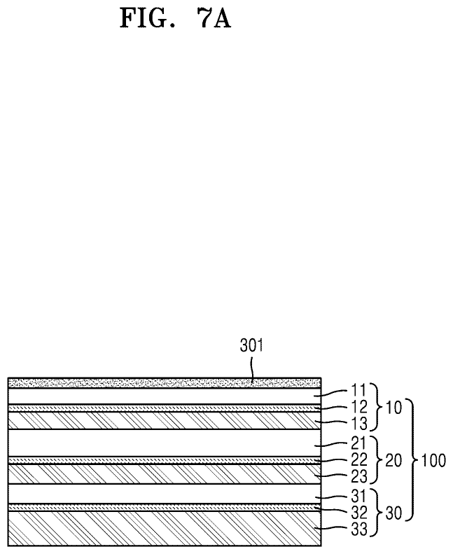

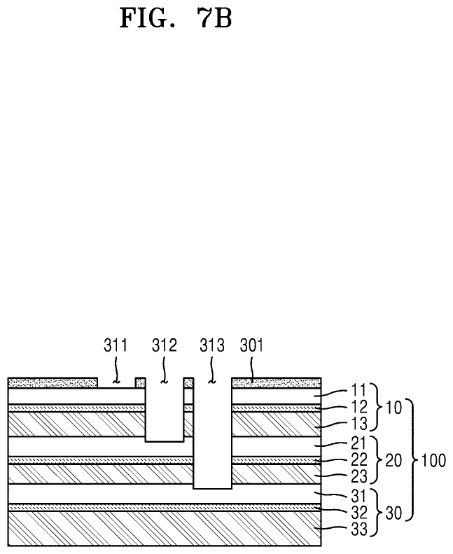

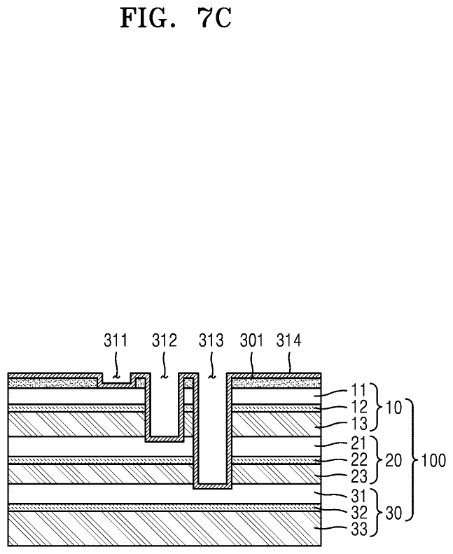

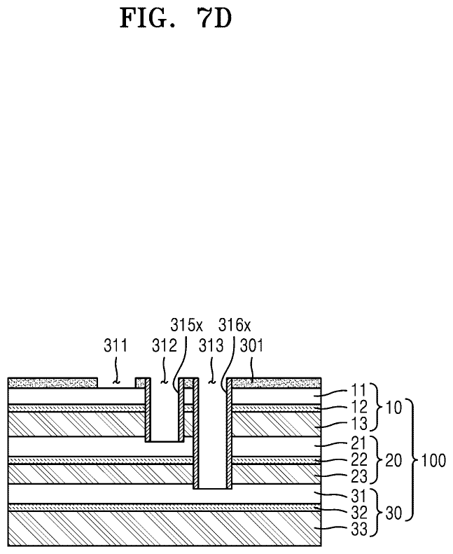

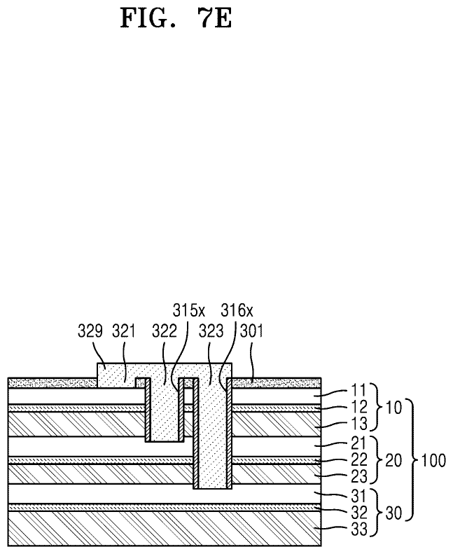

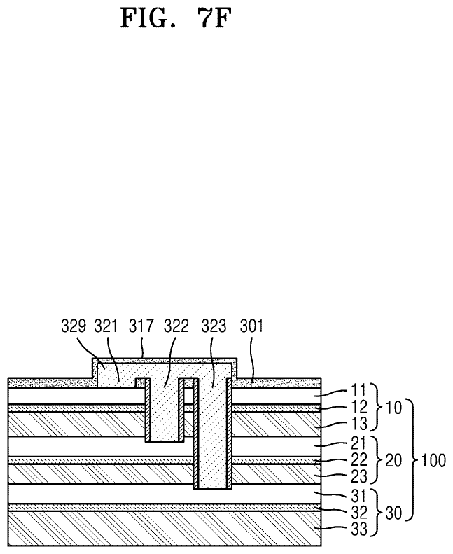

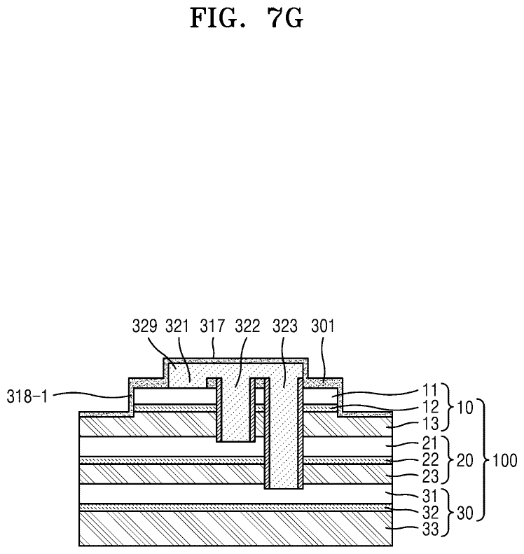

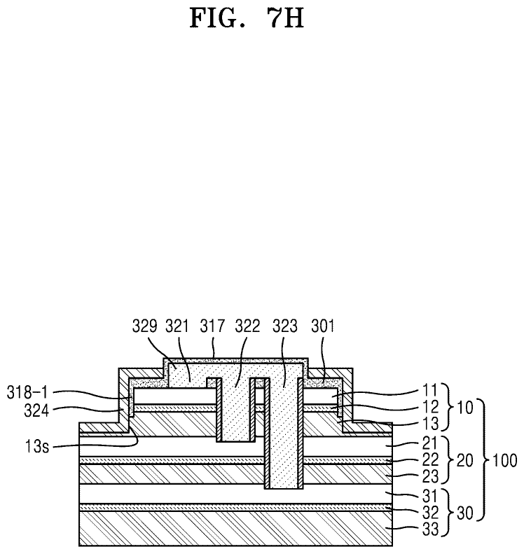

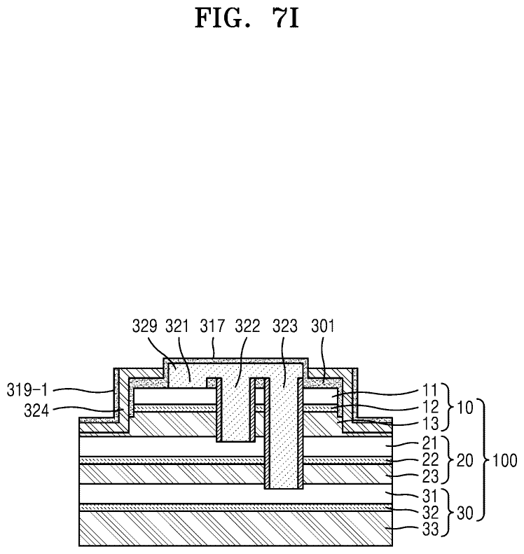

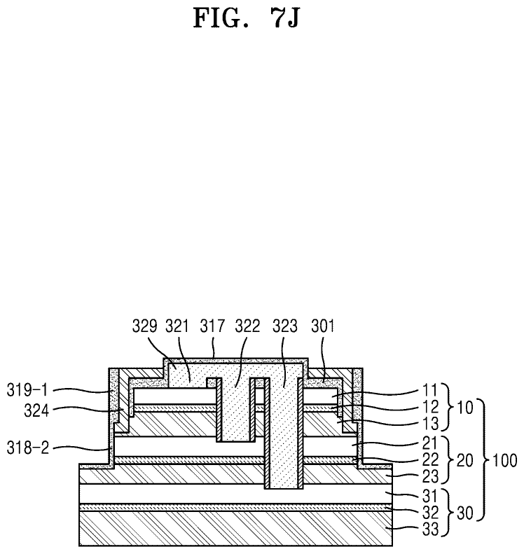

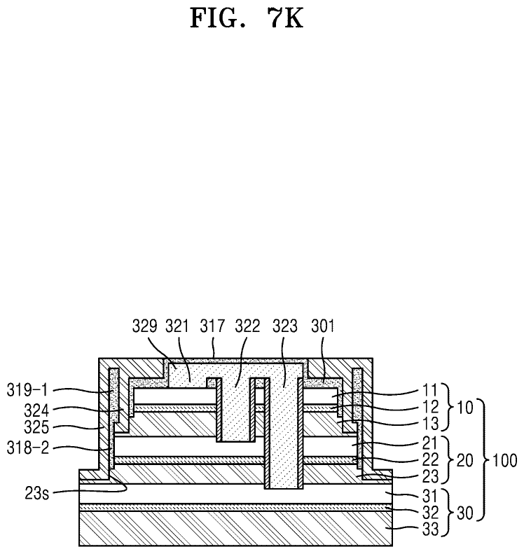

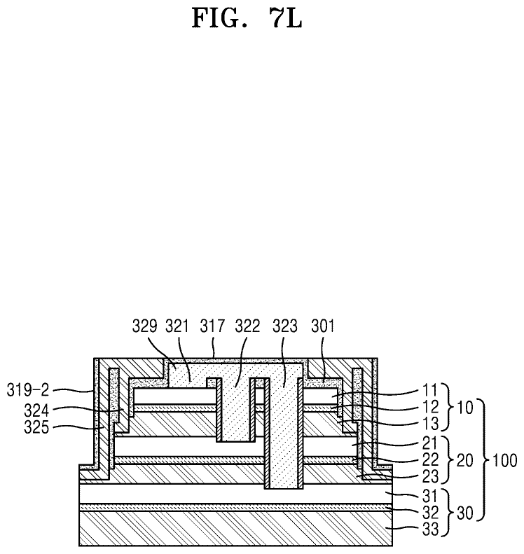

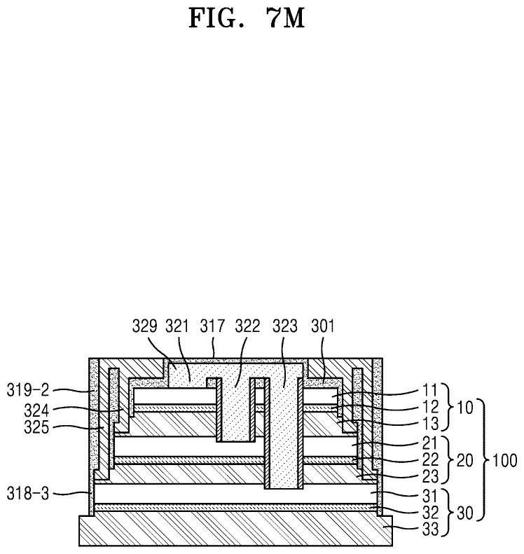

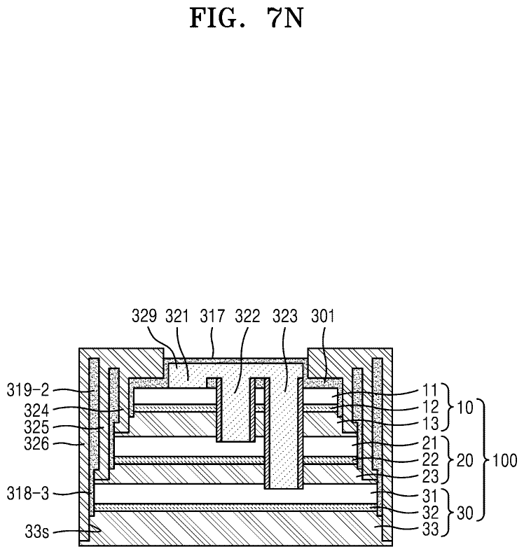

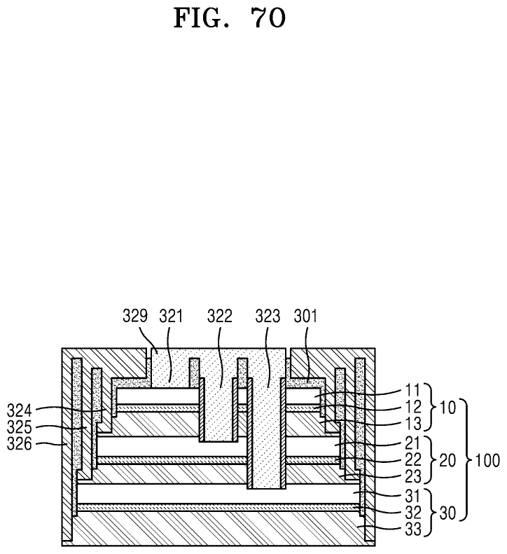

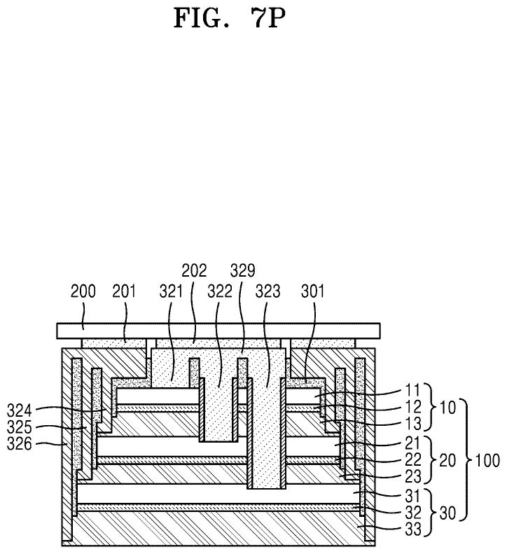

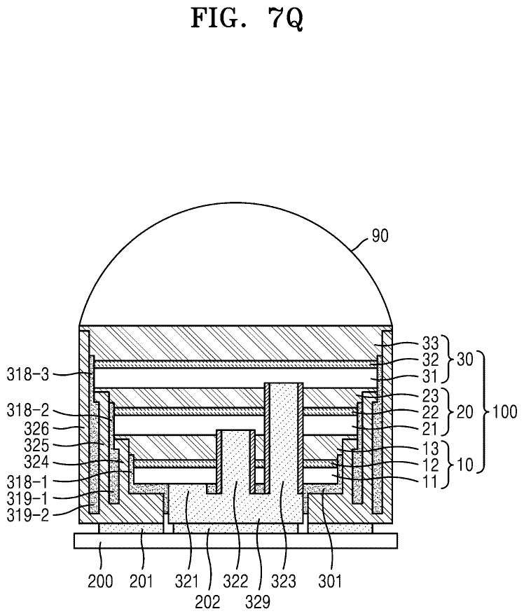

FIGS. 7A through 7Q illustrate an example of a method of manufacturing the light-emitting devices 1 and 1b of FIGS. 1 and 2. An example of a method of manufacturing the light-emitting devices 1 and 1b will be described with reference to FIG. 10A and FIGS. 7A through 7Q.

### Formation of a Light-Emitting Portion

First, a process of forming the light-emitting portion 100 may be performed. Referring to FIG. 7A, the third light-emitting structure 30, the second light-emitting structure 20, and the first light-emitting structure 10 may be sequentially grown and stacked on a growth substrate. The growth substrate may be a growth substrate for semiconductor single crystal growth, and for example, a silicon (Si) substrate, a silicon carbide (SiC) substrate, or a sapphire substrate may be used. In addition, a substrate formed of a material suitable for the growth of a light-emitting structure to be formed on the growth substrate, for example, AlN, AlGaN, ZnO, GaAs, MgAl₂O₄, MgO, LiAlO₂, LiGaO₂, or GaN, may be used. According to some embodiments, a buffer layer for epitaxial growth of a light-emitting structure may be provided on a surface of the growth substrate, and the light-emitting structure may be grown on the buffer layer.

For example, the second conductivity type semiconductor layer 33, the active layer 32, and the first conductivity type semiconductor layer 31 may be sequentially grown on the growth substrate to form the third light-emitting structure 30. The light-emitting structure 30 may be formed of a Group III-V nitride semiconductor material. Examples of the Group III-V nitride semiconductor material may include GaN, InGaN, AlInGaN, and AlGaInP. In the present embodiment, the third light-emitting structure 30 may be formed of a GaN-based semiconductor material. The second conductivity type semiconductor layer 33 may be an n-GaN layer doped with n-type impurities such as Si, Ge, Se, or Te. The active layer 32 may be a layer that emits light due to recombination of electrons and holes, and may have a single quantum well structure or a multi-quantum well structure as described above. For example, a quantum well layer and a barrier layer may be paired in the form of InGaN/GaN, InGaN/InGaN, InGaN/AlGaN, or InGaN/InAlGaN to form a quantum well structure, and bandgap energy may be controlled according to a composition ratio of indium (In) of a material layer including indium (In) to adjust an emission wavelength band. The first conductivity type semiconductor layer 21 may be a p-GaN layer doped with p-type impurities such as Mg, Zn, or Be. The description of the third light-emitting structure 30 may apply to the second light-emitting structure 20 and the first light-emitting structure 10. The first light-emitting structure 10, the second light-emitting structure 20, and the third light-emitting structure 30 may be formed by using hydride vapor phase epitaxy (HVPE), molecular beam epitaxy (MBE), metal organic vapor phase epitaxy (MOVPE), metal organic chemical vapor deposition (MOCVD), other methods, or a combination thereof. Accordingly, the light-emitting portion 100 may be formed.

### Formation of a Passivation Layer

Next, a passivation layer 301 may be formed by depositing a dielectric material on the first light-emitting structure 10. The dielectric material may include, for example, SiO₂, TiO₂, Si₃N₄, AlOₓ, AlOₓN_{y}, Ta₂O₅, TiN, AlN, ZrO₂, TiAlN, TiSiN, HfOₓ, ZAZ, or any of various combinations thereof. In the present embodiment, the passivation layer 301 may be formed of SiO₂, which is a light-transmitting dielectric material. For example, the passivation layer 301 may be formed by using sputtering, atomic layer deposition (ALD), plasma enhanced atomic layer deposition (PEALD), chemical vapor deposition (CVD), plasma enhanced chemical vapor deposition (PECVD), physical vapor deposition (PVD), other methods, or a combination thereof. In the present embodiment, the passivation layer 301 may be formed by ALD. The passivation layer 301 may correspond to the passivation layer 80 of FIGS. 1 and 2.

Alternatively, the passivation layer 301, the first light-emitting structure 10, the second light-emitting structure 20, and the third light-emitting structure 30 may be sequentially formed on a growth substrate, and a resultant structure may be transferred to a transfer substrate to obtain a resultant structure of FIG. 7A. In this case, each of the first light-emitting structure 10, the second light-emitting structure 20, and the third light-emitting structure 30 may be epitaxially grown in the order of a first conductivity type semiconductor layer, an active layer, and a second conductivity type semiconductor layer. However, embodiments of the disclosure are not limited thereto, and, after the first light-emitting structure 10, the second light-emitting structure 20, and the third light-emitting structure 30 are individually epitaxially grown on the growth substrate, the third light-emitting structure 30, the second light-emitting structure 20, and the first light-emitting structure 10 may be sequentially transferred to the transfer substrate, and the passivation layer 301 may be formed on the first light-emitting structure 10.

### Formation of a First Common Electrode

First, referring to FIG. 7B, the passivation layer 301 and the light-emitting portion 100 may be etched to form via holes 311, 312, and 313 through which the first conductivity type semiconductor layers 11, 21, and 31 of the first light-emitting structure 10, the second light-emitting structure 20, and the third light-emitting structure 30 are exposed, respectively. This process may be performed by using, for example, a dry etching process. The dry etching process may use, for example, inductively coupled plasma (ICP).

Next, referring to FIG. 7C, a dielectric material, for example, SiO₂, may be deposited on a surface of the passivation layer 301 and inner walls of the via holes 311, 312, and 313 to form a passivation layer 314. Portions of the passivation layer 314 on the surface of the passivation layer 301 and the bottoms of the via holes 311, 312, and 313 may be removed by using, for example, a dry etching process, so that portions of the passivation layer 314 on the inner walls of the via holes 312 and 313 remains. Accordingly, as shown in FIG. 7D, passivation elements 315x and 316x may be formed on the inner walls of the via holes 312 and 313, and the passivation elements 315x and 316x may correspond to the passivation elements 72x and 73x of FIGS. 1 and 2.

As shown in FIG. 7E, an electrode material may be deposited and filled in the via holes 311, 312, and 313 and a top surface of the passivation layer 301 to form electrodes 321, 322, and 323 and an electrode 329. The electrodes 321, 322, and 323 may be connected to each other by the electrode 329. The electrode material may include, for example, Al, Ti, Pt, Ag, Au, Pd, TiW, or any of various combinations thereof. The electrode material may also include a transparent electrode material, for example, ITO. The deposition of the electronic material may be performed by using sputtering, atomic layer deposition (ALD), plasma enhanced atomic layer deposition (PEALD), chemical vapor deposition (CVD), plasma enhanced chemical vapor deposition (PECVD), physical vapor deposition (PVD), other methods, or a combination thereof. The electrode 329 and the electrodes 321, 322, and 323 may respectively correspond to the first common portion 79 and the first electrode portions 71, 72, and 73 in FIGS. 1 and 2.

### Formation of Second Common Electrode and Separation Layer

As shown in FIG. 7F, in order to protect the electrodes 321, 322, 323, and 329 in a mesa etching process described below, for example, SiO₂ may be deposited to form a protective mask 317 covering the electrodes 321, 322, 323, and 329. As shown in FIG. 7G, the first conductivity type semiconductor layer 11 and the active layer 12 of the first light-emitting structure 10 may be mesa-etched. The etching may be performed by using a dry etching process or a wet etching process. The dry etching process may use, for example, ICP. The wet etching process may be performed by using, for example, a potassium hydroxide (KOH) solution or a tetramethyl ammonium hydroxide (TMAH) solution as an etching solution. The etching may be performed on partially up to the second conductivity type semiconductor layer 13 of the first light-emitting structure 10 beyond the active layer 12 of the first light-emitting structure 10. A dielectric material may be deposited on side surfaces of the first conductivity type semiconductor layer 11 and the active layer 12 and a surface of the second conductivity type semiconductor layer 13 which are exposed after the etching, to thereby form a passivation layer 318-1. In the present embodiment, the passivation layer 318-1 may be formed of SiO₂. Next, as shown in FIG. 7H, the second conductivity type semiconductor layer 13 of the first light-emitting structure 10 may be partially mesa-etched to expose a side surface 13s of the second conductivity type semiconductor layer 13. Next, an electrode material may be deposited to contact the side surface 13s of the second conductivity type semiconductor layer 13 and extend in the stacking direction to cover the passivation layer 318-1, to form an electrode 324 partially covering a top surface of the passivation layer 301. The passivation layer 318-1 may correspond to the separation layer 51 of FIGS. 1 and 2. A portion of the electrode 324 contacting the side surface 13s of the second conductivity type semiconductor layer 13 may correspond to the second electrode portion 41 of FIGS. 1 and 2, and a portion of the electrode 324 covering an upper portion of the passivation layer 301 may correspond to the second common portion 49 of FIGS. 1 and 2.

The processes of FIGS. 7F through 7H may be sequentially performed on the second light-emitting structure 20 and the third light-emitting structure 30.

As shown in FIG. 7I, in order to protect the electrode 324 in a mesa etching process described below, for example, SiO₂ may be deposited to form a passivation layer 319-1 covering the electrode 324. As shown in FIG. 7J, the first conductivity type semiconductor layer 21 and the active layer 22 of the second light-emitting structure 20 may be partially mesa-etched up to the second conductivity type semiconductor layer 23. The etching may be performed by using a dry etching process or a wet etching process. A dielectric material, for example, SiO₂, may be deposited on side surfaces of the first conductivity type semiconductor layer 21 and the active layer 22 and a surface of the second conductivity type semiconductor layer 23 which are exposed after the etching, to thereby form a passivation layer 318-2. Next, as shown in FIG. 7K, the second conductivity type semiconductor layer 23 of the second light-emitting structure 20 may be partially mesa-etched to expose a side surface 23s of the second conductivity type semiconductor layer 23. Next, an electrode material may be deposited to contact the side surface 23s of the second conductivity type semiconductor layer 23 and extends in the stacking direction to cover a passivation layer 319-1, to form an electrode 325 connected to the portion of the electrode 324 covering the upper portion of the passivation layer 301. The passivation layer 319-1 may correspond to the protective layer 61 of FIGS. 1 and 2. The passivation layer 318-2 may correspond to the separation layer 52 of FIGS. 1 and 2. A portion of the electrode 325 contacting the side surface 23s of the second conductivity type semiconductor layer 23 may correspond to the second electrode portion 42 of FIGS. 1 and 2, and a portion of the electrode 325 connected to the electrode 324 may correspond to the second common portion 49 of FIGS. 1 and 2.

As shown in FIG. 7L, in order to protect the electrode 325 in a mesa etching process described below, for example, SiO₂ may be deposited to form a passivation layer 319-2 covering the electrode 325. As shown in FIG. 7M, up to the second conductivity type semiconductor layer 33 of the third light-emitting structure 30 beyond the first conductivity type semiconductor layer 31 and the active layer 32 of the third light-emitting structure 30 may be partially mesa-etched. The etching may be performed by using a dry etching process or a wet etching process. A dielectric material, for example, SiO₂, may be deposited on side surfaces of the first conductivity type semiconductor layer 31 and the active layer 32 and a surface of the second conductivity type semiconductor layer 33 which are exposed after the etching, to thereby form a passivation layer 318-3. Next, as shown in FIG. 7N, the second conductivity type semiconductor layer 33 of the third light-emitting structure 30 may be partially mesa-etched to expose a side surface 33s of the second conductivity type semiconductor layer 33. Next, an electrode material may be deposited to contact the side surface 33s of the second conductivity type semiconductor layer 33 and extend in the stacking direction to cover the passivation layer 319-2, to form an electrode 326 connected to the portion of the electrode 325 covering the upper portion of the passivation layer 301. The passivation layer 319-2 may correspond to the protective layer 62 of FIGS. 1 and 2. The passivation layer 318-3 may correspond to the separation layer 53 of FIGS. 1 and 3. A portion of the electrode 326 contacting the side surface 33s of the second conductivity type semiconductor layer 33 may correspond to the second electrode portion 43 of FIGS. 1 and 2, and a portion of the electrode 326 connected to the electrode 325 may correspond to the second common portion 49 of FIGS. 1 and 2.

### Bonding

Next, as shown in FIG. 7O, the protective mask 317 may be removed to expose the electrode 329. Next, as shown in FIG. 7P, portions of the electrodes 324, 325, and 326 located on the top surface of the passivation layer 301 and the electrode 329 may be bonded to the bonding pads 201 and 202 of the substrate 200 of the display panel. Accordingly, the light-emitting device 1 of FIG. 1 may be manufactured.

### Formation of Lens

The lens 90 may be formed on the light-emitting portion 100. A method of forming the lens 90 is not particularly limited. In the state of FIG. 7P, the light-emitting portion 100 may be turned over so that the third light-emitting structure 30 becomes an uppermost layer in the stacking direction as shown in FIG. 7Q. Next, a thermoplastic material may be stacked on the third light-emitting structure 30 to form a light-transmitting layer. The thermoplastic material may include, for example, photoresist, polyester, acryl, or epoxy. A shape of the light-transmitting layer may be, for example, a cylindrical shape. Next, for example, a thermal reflow process may be performed to form the light-transmitting layer having a rectangular shape into a dome-shaped lens shape. A curvature of the lens 90 may be adjusted according to surface energy of a top surface of the third light-emitting structure 30, a contact angle of the light-transmitting layer, a thickness and a width of the light-transmitting layer, and a thermal reflow process temperature. Accordingly, the light-emitting device 1b of FIG. 2 may be manufactured.

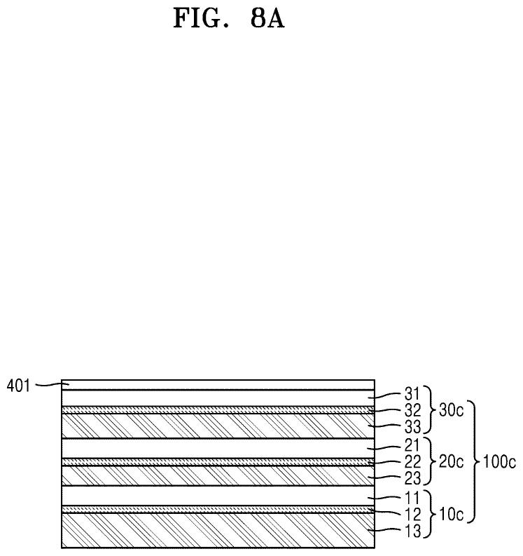

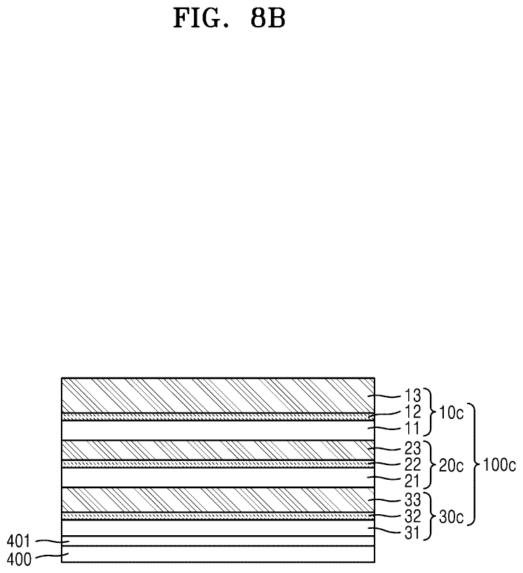

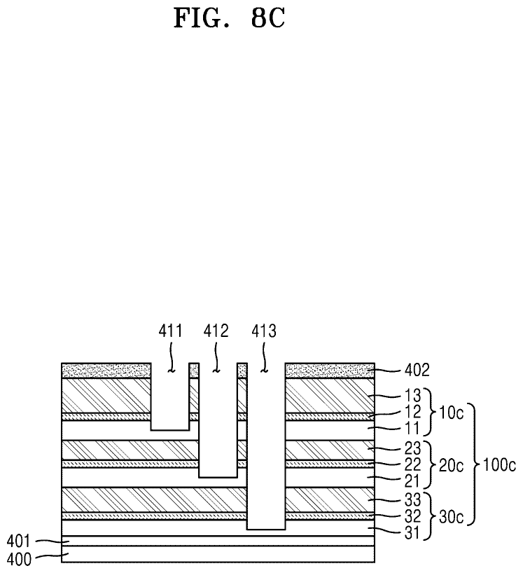

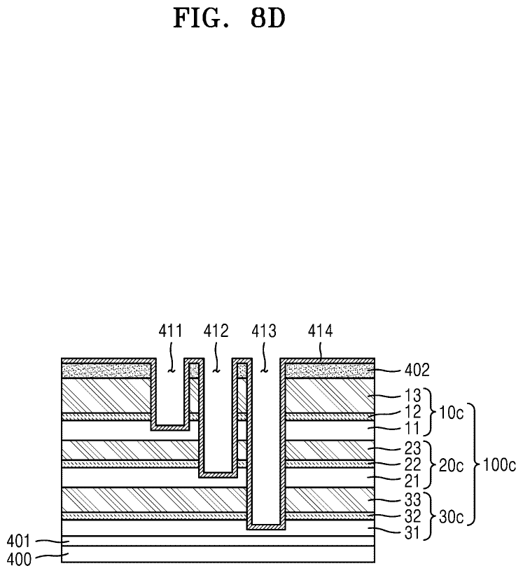

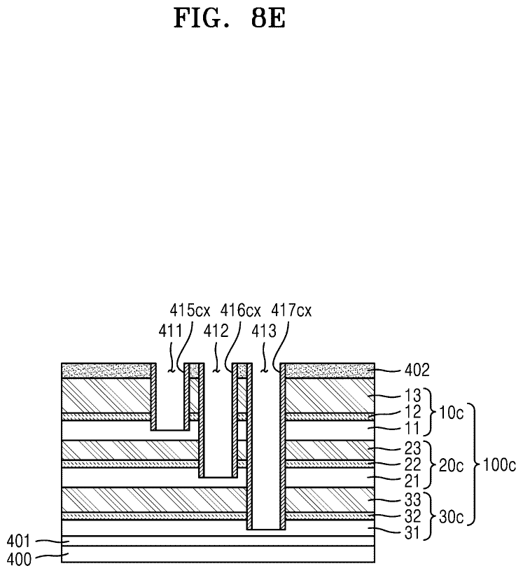

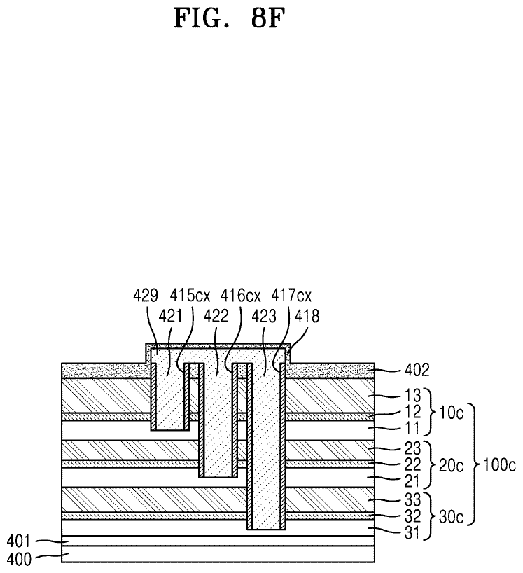

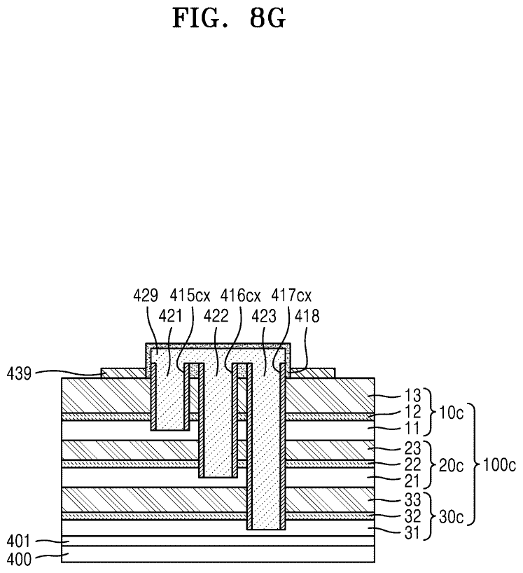

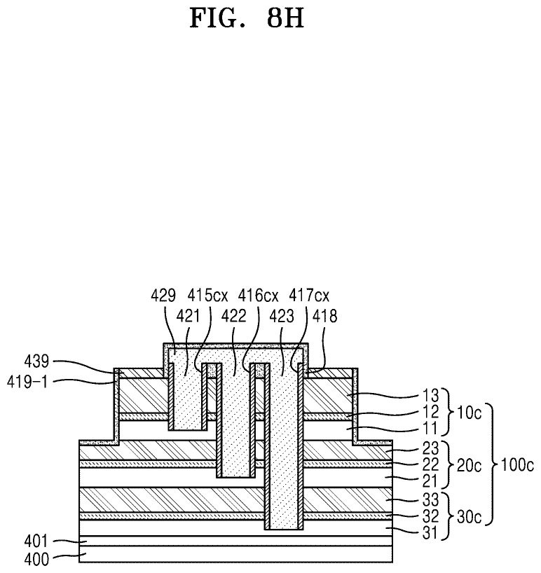

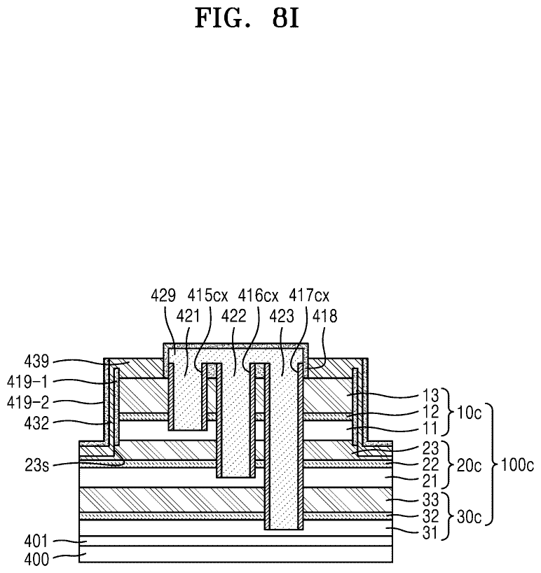

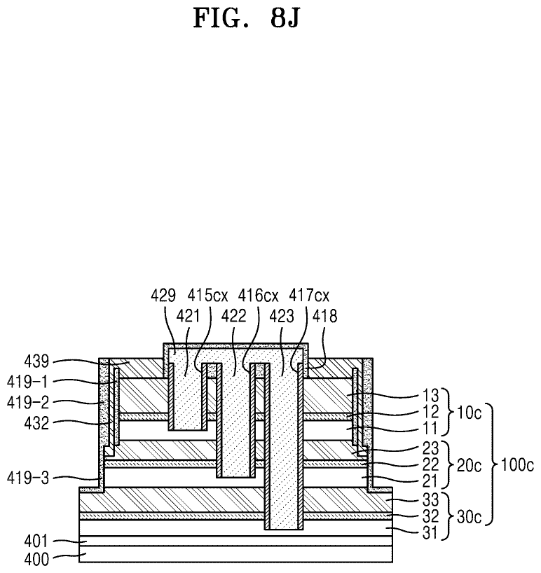

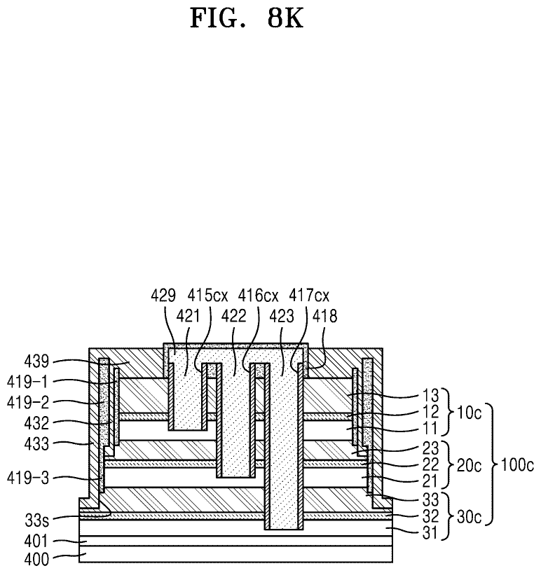

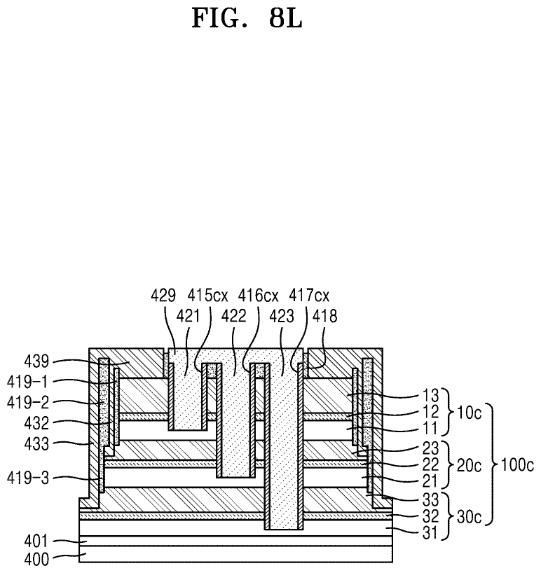

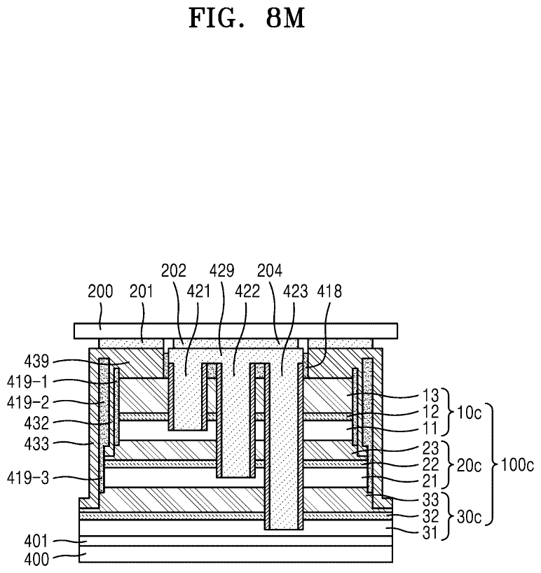

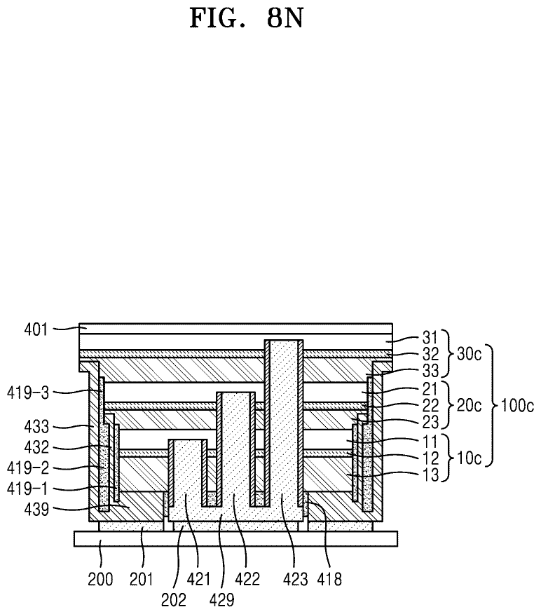

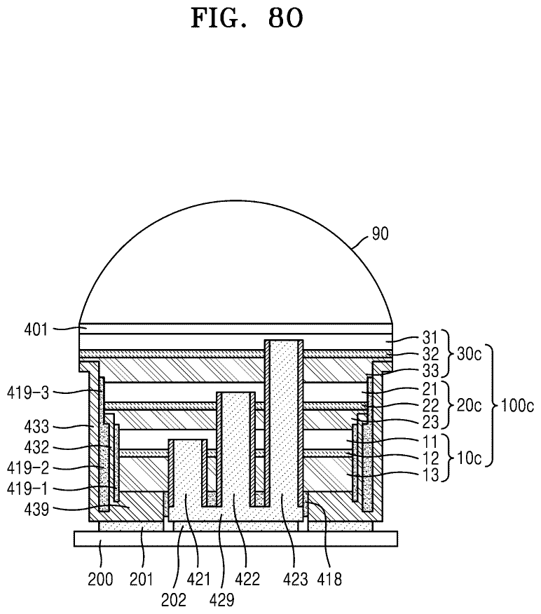

FIGS. 8A through 8O illustrate an example of a method of manufacturing the light-emitting device 1c of FIG. 5. The method of manufacturing the light-emitting device 1c of FIG. 5 will now be described with reference to FIG. 10A and FIGS. 8A through 8O.

### Formation of Light-Emitting Portion and Passivation Layer

First, as shown in FIG. 8A, a process may be performed in which the first light-emitting structure 10c, the second light-emitting structure 20c, and the third light-emitting structure 30c are epitaxially grown on a growth substrate to form the light-emitting portion 100c, and a passivation layer 401 may be formed on a top surface of the light-emitting portion 100c. This process may be the same as the process described above with reference to FIG. 7A, and thus, a repeated description thereof may be omitted. Alternatively, the passivation layer 401, the third light-emitting structure 30c, the second light-emitting structure 20c, and the first light-emitting structure 10c may be sequentially formed on the growth substrate, and a resultant structure may be transferred to a transfer substrate to obtain a resultant structure of FIG. 8A. In this case, each of the first light-emitting structure 10c, the second light-emitting structure 20c, and the third light-emitting structure 30c may be epitaxially grown in the order of a first conductivity type semiconductor layer, an active layer, and a second conductivity type semiconductor layer. However, embodiments of the disclosure are not limited thereto, and, after the first light-emitting structure 10c, the second light-emitting structure 20c, and the third light-emitting structure 30c are individually epitaxially grown on the growth substrate, the first light-emitting structure 10c, the second light-emitting structure 20c, and the third light-emitting structure 30c may be sequentially transferred to the transfer substrate, and the passivation layer 401 may be formed on the third light-emitting structure 30c. The passivation layer 401 may include, for example, a dielectric material. The dielectric material may include, for example, SiO₂, TiO₂, Si₃N₄, AlOₓ, AlOₓN_{y}, Ta₂O₅, TiN, AlN, ZrO₂, TiAlN, TiSiN, HfOₓ, ZAZ, or any of various combinations thereof. In the present embodiment, the passivation layer 401 may be formed of SiO₂, which is a light-transmitting dielectric material.

### Formation of a First Common Electrode

Referring to FIG. 8B, a dummy substrate 400 may be bonded to the passivation layer 401 of the resultant structure of FIG. 8A and then may be turned over, and the grown substrate may be removed. Next, an exposed top surface of the first light-emitting structure 10c may be ground and planarized.

Referring to FIG. 8C, a dielectric material may be deposited on the top surface of the first light-emitting structure 10c to form a protective mask layer 402. The dielectric material may include, for example, SiO₂, TiO₂, Si₃N₄, AlOₓ, AlOₓN_{y}, Ta₂O₅, TiN, AlN, ZrO₂, TiAlN, TiSiN, HfOₓ, ZAZ, or any of various combinations thereof. In the present embodiment, the protective mask layer 402 may be formed of SiO₂, which is a light-transmitting dielectric material. For example, the protective mask layer 402 may be formed by using sputtering, atomic layer deposition (ALD), plasma enhanced atomic layer deposition (PEALD), chemical vapor deposition (CVD), plasma enhanced chemical vapor deposition (PECVD), physical vapor deposition (PVD), other methods, or a combination thereof. In the present embodiment, the protective mask layer 402 may be formed by ALD.

Then, the protective mask layer 402 and the light-emitting portion 100c may be etched to form via holes 411, 412, and 413 through which the first conductivity type semiconductor layers 11, 21, and 31 of the first light-emitting structure 10c, the second light-emitting structure 20c, and the third light-emitting structure 30c are exposed, respectively. This process may be performed by using, for example, a dry etching process. The dry etching process may use, for example, ICP.

Referring to FIG. 8D, a dielectric material, for example, SiO₂, may be deposited on a surface of the protective mask layer 402 and inner walls of the via holes 411, 412, and 413 to form a passivation layer 414. Portions of the passivation layer 414 on the surface of the protective mask layer 402 and the bottoms of the via holes 411, 412, and 413 may be removed by using, for example, a dry etching process, so that portions of the passivation layer 414 on the inner walls of the via holes 411, 412, and 413 remain. Accordingly, as shown in FIG. 8E, passivation layers 415x, 416x, and 417x may be formed on the inner walls of the via holes 411, 412, and 413, and the passivation layers 415x, 416x, and 417x may correspond to the passivation elements 71cx, 72cx, and 73cx of FIG. 5.

As shown in FIG. 8F, an electrode material may be deposited and filled in the via holes 411, 412, and 413 and a top surface of the protective mask layer 402 to form electrodes 421, 422, and 423 and an electrode 429. The electrodes 421, 422, and 423 may be connected to each other by the electrode 429. The electrode material may include, for example, Al, Ti, Pt, Ag, Au, Pd, TiW, or any of various combinations thereof. The electrode material may also include a transparent electrode material, for example, ITO. The deposition of the electronic material may be performed by using sputtering, atomic layer deposition (ALD), plasma enhanced atomic layer deposition (PEALD), chemical vapor deposition (CVD), plasma enhanced chemical vapor deposition (PECVD), physical vapor deposition (PVD), other methods, or a combination thereof. The electrodes 421, 422, and 423 may correspond to the first electrode portions 71c, 72c, and 73c in FIG. 5, respectively. The electrode 429 may correspond to the first common portion 79c in FIG. 5. Then, in order to protect the electrodes 421, 422, 423, and 429 in a mesa etching process described below, for example, SiO₂ may be deposited to form a passivation layer 418 covering the electrodes 421, 422, 423, and 429. The passivation layer 418 may correspond to the passivation layer 80 of FIG. 5.

### Formation of Second Common Electrode and Separation Layer

As shown in FIG. 8G, the protective mask layer 402 formed on the top surface of the first light-emitting structure 10c may be partially removed to expose a top surface of the second conductivity type semiconductor layer 13 of the first light-emitting structure 10c. Next, an electrode material may be deposited on the exposed top surface of the second conductivity type semiconductor layer 13 to form an electrode 439. The electrode material may include, for example, Al, Ti, Pt, Ag, Au, Pd, TiW, or any of various combinations thereof. The electrode material may also include a transparent electrode material, for example, ITO. The electrode 439 may correspond to the second common portion 49c of FIG. 5 and also may function as the second electrode portion 41 of FIGS. 1 and 2.

As shown in FIG. 8H, the second conductivity type semiconductor layer 13, the active layer 12, and the first conductivity type semiconductor layer 11 of the first light-emitting structure (10c) may be partially mesa-etched up to the second conductivity type semiconductor layer 23 of the second light-emitting structure 20c. The etching may be performed by using a dry etching process or a wet etching process. The dry etching process may use, for example, ICP. The wet etching process may be performed by using, for example, a potassium hydroxide (KOH) solution or a tetramethyl ammonium hydroxide (TMAH) solution as an etching solution. A dielectric material may be deposited on side surfaces of the second conductivity type semiconductor layer 13, the active layer 12, and the first conductivity type semiconductor layer 11 of the first light-emitting structure 10c and a surface of the second conductivity type semiconductor layer 23 of the second light-emitting structure 20c which are exposed after the etching, to thereby form a passivation layer 419-1. In the present embodiment, the passivation layer 419-1 may be formed of SiO₂.

Next, as shown in FIG. 8I, the passivation layer 419-1 on the surface of the second conductivity type semiconductor layer 23 of the second light-emitting structure 20c and the second conductivity type semiconductor layer 23 of the second light-emitting structure 20c may be partially mesa-etched to expose the side surface 23s of the second conductivity type semiconductor layer 23. Next, an electrode material may be deposited to contact the side surface 23s of the second conductivity type semiconductor layer 23, and extend in the stacking direction to form an electrode 432 stacked to an upper portion of the electrode 439. The passivation layer 419-1 may correspond to the separation layer 51c of FIG. 5. A portion of the electrode 432 contacting the side surface 23s of the second conductivity type semiconductor layer 23 may correspond to the second electrode portion 42c of FIG. 5, and a portion of the electrode 432 covering the upper portion of the electrode 439 may correspond to the second common portion 49c of FIG. 5 together with the electrode 439. Next, in order to protect the electrode 432 in a mesa etching process described below, for example, SiO₂ may be deposited to form a passivation layer 419-2 covering the electrode 432.

As shown in FIG. 8J, portions of the electrode 432 and the passivation layer 419-2 on the second conductivity type semiconductor layer 23 of the second light-emitting structure 20c, and up to the second conductivity type semiconductor layer 33 of the third light-emitting structure 30c beyond the second conductivity type semiconductor layer 23, the active layer 22, and the first conductivity type semiconductor layer 21 of the second light-emitting structure 20c may be partially mesa-etched. The etching may be performed by using a dry etching process or a wet etching process. A dielectric material, for example, SiO₂, may be deposited on side surfaces of the active layer 22 and the first conductivity type semiconductor layer 21 and a surface of the second conductivity type semiconductor layer 33 of the third light-emitting structure 30c which are exposed after the etching, to thereby form a passivation layer 419-3. Next, as shown in FIG. 8K, the second conductivity type semiconductor layer 33 of the third light-emitting structure 30c may be partially mesa-etched to expose a side surface 33s of the second conductivity type semiconductor layer 33. Next, an electrode material may be deposited to contact the side surface 33s of the second conductivity type semiconductor layer 33, and extend in the stacking direction to form an electrode 433 connected to the electrode 439. The passivation layer 419-2 may correspond to the protective layer 60c of FIG. 5. The passivation layer 419-3 correspond to the separation layer 52c of FIG. 5. The electrode 433 correspond to the second electrode portion 43c of FIG. 5.

### Bonding

Next, as shown in FIG. 8L, a portion of the passivation layer 418 may be removed to expose the electrode 429. Next, as shown in FIG. 8M, portions of electrodes 432, 433, and 439 located on a top surface of the passivation layer 418 and an exposed portion of the electrode 429 may be bonded to the bonding pads 201 and 202 of the substrate 200 of the display panel. In the state of FIG. 8M, the light-emitting portion 100c may be turned over so that the third light-emitting structure 30c becomes an uppermost layer in the stacking direction as shown in FIG. 8N. Then, a dummy substrate 400 may be removed.

### Formation of a Lens

Next, the lens 90 may be formed on the light-emitting portion 100c. A method of forming the lens 90 is not particularly limited. Referring to FIG. 8O, a thermoplastic material may be stacked on the passivation layer 401 on the third light-emitting structure 30c to form a light-transmitting layer. The thermoplastic material may include, for example, photoresist, polyester, acryl, or epoxy. A shape of the light-transmitting layer may be, for example, a cylindrical shape. Next, for example, a thermal reflow process may be performed to form the light-transmitting layer having a rectangular shape into a dome-shaped lens shape. A curvature of the lens 90 may be adjusted according to surface energy of a top surface of the passivation layer 401, a contact angle of the light-transmitting layer, a thickness and a width of the light-transmitting layer, and a thermal reflow process temperature. Accordingly, the light-emitting device 1c of FIG. 5 may be manufactured.

FIG. 10B is a flowchart of an embodiment of a method of manufacturing a light-emitting device. Referring to FIG. 10B, an embodiment of a method of manufacturing a light-emitting device may include an operation S21 of forming a light-emitting portion including a plurality of light-emitting structures, an operation S22 of forming a passivation layer on one surface of the light-emitting portion, an operation S23 of forming, in side portions of the second conductivity type semiconductor layers of a plurality of light-emitting structures, a plurality of concave portions that are concave with respect to first conductivity type semiconductor layers and active layers of the plurality of light-emitting structures, an operation S24 of forming a first common portion on the passivation layer, a first common electrode including a plurality of first electrode portions extending from the first common portion and electrically contacting first conductivity type semiconductor layers of the plurality of light-emitting structures, wherein at least one of the first electrode portions has a conductive via structure, and a second common portion spaced apart from the first common portion, an operation S25 of forming a separation layer including a plurality of openings exposing the plurality of concaves, on a side portion of the light-emitting portion, and an operation S26 of forming a second common electrode including a plurality of second electrode portions each extending along the separation layer from the second common portion to respectively contact side surfaces of the second conductivity type semiconductor layers of the plurality of light-emitting structures through the plurality of openings of the separation layer.

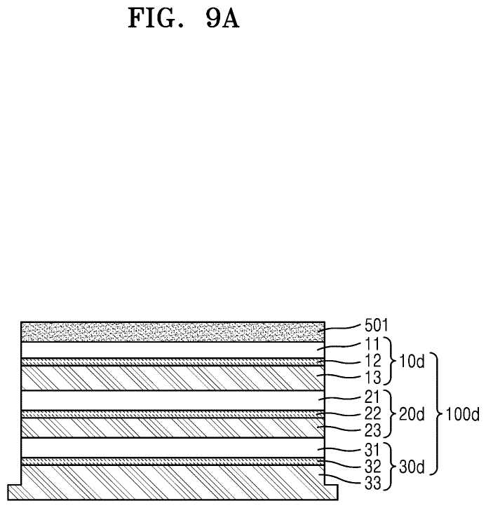

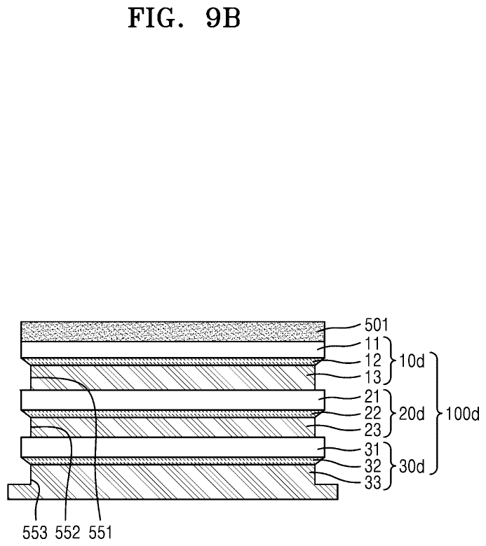

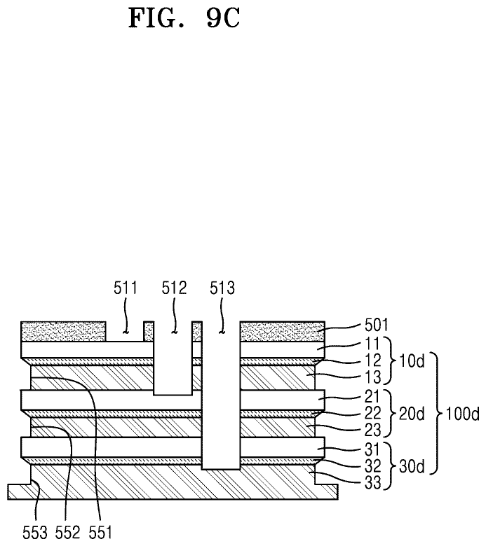

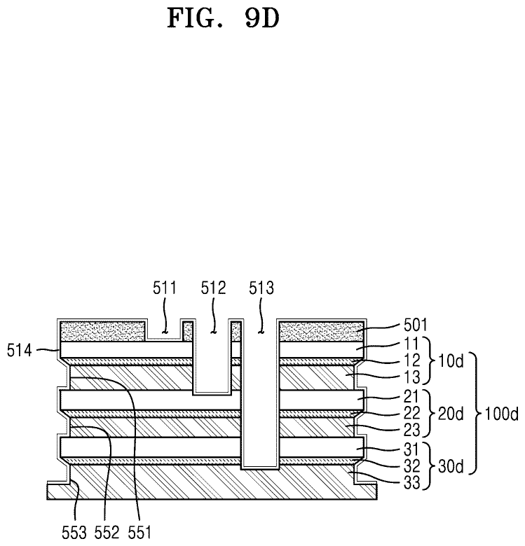

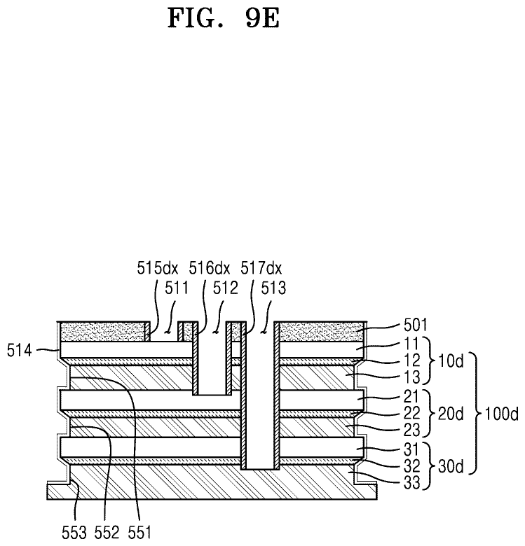

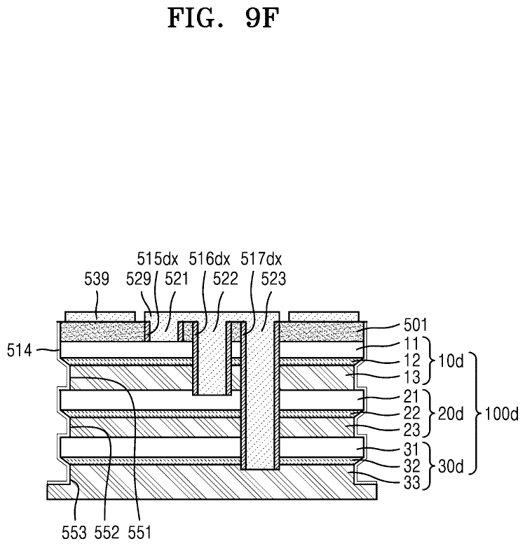

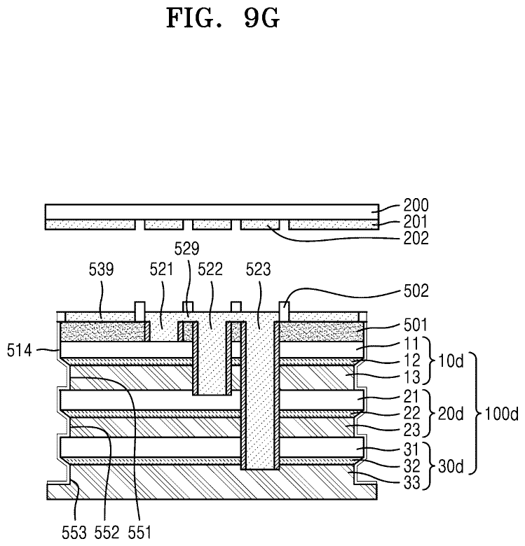

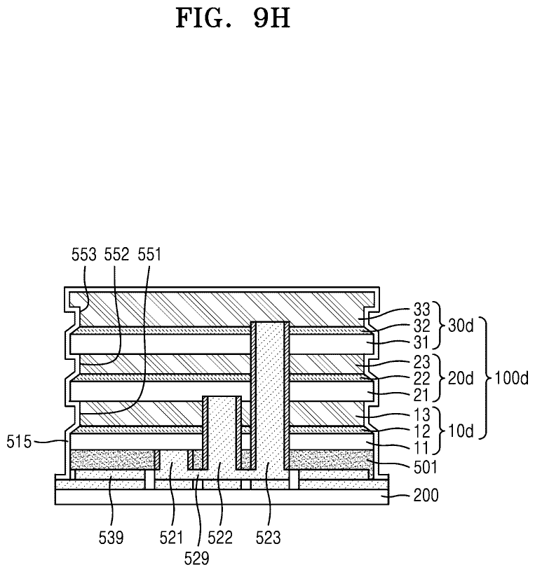

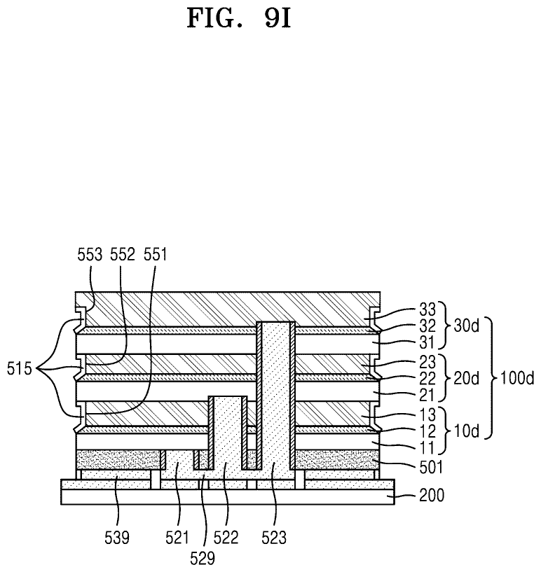

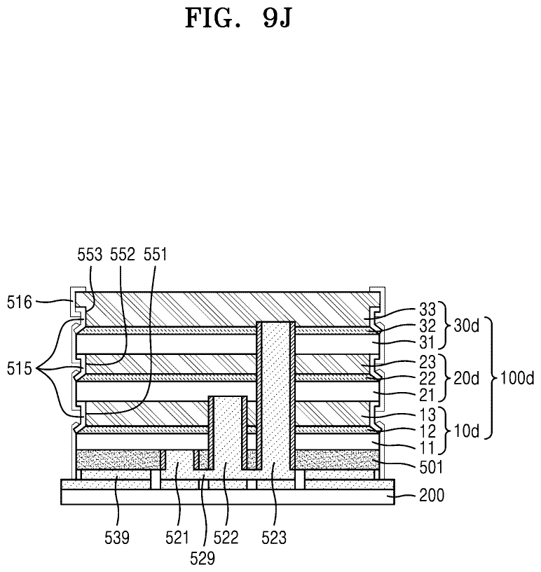

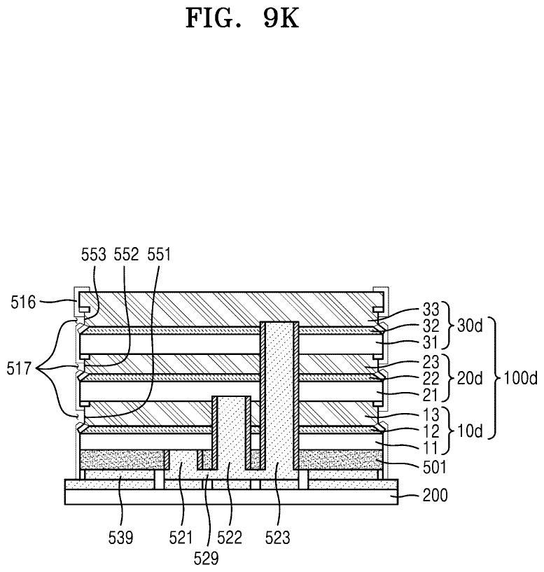

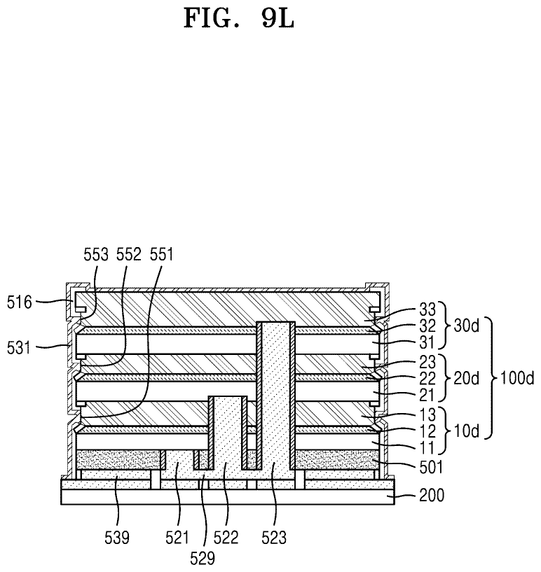

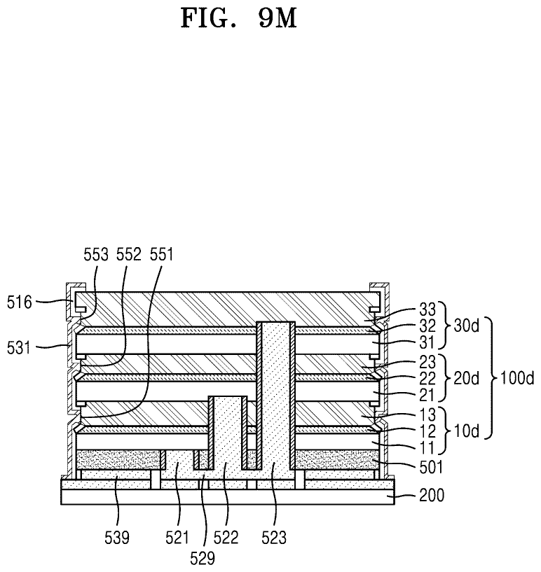

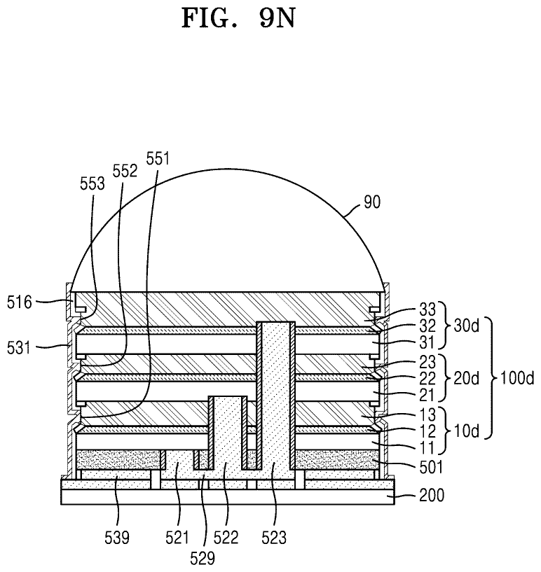

FIGS. 9A through 9N illustrate an example of a method of manufacturing the light-emitting device 1d of FIG. 6. The method of manufacturing the light-emitting device 1d of FIG. 6 will now be described with reference to FIG. 10B and FIGS. 9A through 9N.

### Formation of Light-Emitting Portion and Passivation Layer

First, as shown in FIG. 9A, the third light-emitting structure 30d, the second light-emitting structure 20d, and the first light-emitting structure 10d may be epitaxially grown on a growth substrate to form the light-emitting portion 100d. Then, a dielectric material may be deposited on a top surface of the light-emitting portion 100d to form a passivation layer 501. The dielectric material may include, for example, SiO₂, TiO₂, Si₃N₄, AlOₓ, AlOₓN_{y}, Ta₂O₅, TiN, AlN, ZrO₂, TiAlN, TiSiN, HfOₓ, ZAZ, or any of various combinations thereof. In the present embodiment, the passivation layer 501 may be formed of SiO₂, which is a light-transmitting dielectric material. In this case, each of the third light-emitting structure 30d, the second light-emitting structure 20d, and the first light-emitting structure 10d may have a structure in which a second conductivity type semiconductor layer, an active layer, and a first conductivity type semiconductor layer are sequentially epitaxially grown. The description of FIG. 7A may be applied to FIG. 9A.

Alternatively, the passivation layer 501, the first light-emitting structure 10d, the second light-emitting structure 20d, and the third light-emitting structure 30d may be sequentially formed on the growth substrate, and a resultant structure may be transferred to a transfer substrate to obtain a resultant structure of FIG. 9A. In this case, each of the first light-emitting structure 10d, the second light-emitting structure 20d, and the third light-emitting structure 30d may have a structure in which a first conductivity type semiconductor layer, an active layer, and a second conductivity type semiconductor layer are epitaxially grown in this stated order. However, embodiments of the disclosure are not limited thereto, and, after the first light-emitting structure 10d, the second light-emitting structure 20d, and the third light-emitting structure 30d are individually epitaxially grown on the growth substrate, the third light-emitting structure 30d, the second light-emitting structure 20d, and the first light-emitting structure 10d may be sequentially transferred to the transfer substrate, and the passivation layer 501 may be formed on the top surface of the first light-emitting structure 10d.

Then, a mask layer may be formed on a top surface of the passivation layer 501, and the passivation layer 501 and the light-emitting portion 100d may be mesa-etched. The mask layer may be, for example, an SiN layer. The etching may be performed by using a dry etching process or a wet etching process. The dry etching process may use, for example, ICP. The wet etching process may be performed by using, for example, a potassium hydroxide (KOH) solution or a tetramethyl ammonium hydroxide (TMAH) solution as an etching solution.

### Formation of a Plurality of Concave Portions

Next, a process of forming concave portions 13r, 23r, and 33r on side portions of the second conductivity type semiconductor layers 13, 23, and 33 of the first light-emitting structure 10d, the second light-emitting structure 20d, and the third light-emitting structure 30d may be performed.

To this end, the side surface of the light-emitting portion 100d may be etched. The etching may be performed by using an OH-based etchant, for example, a potassium hydroxide (KOH) solution or a tetramethyl ammonium hydroxide (TMAH) solution. Etching rates of these etchants with respect to a GaN-based material depend on whether the GaN-based material is doped and the type of dopant. For example, the etching rates of these etchants with respect to n-GaN are much greater than the etching rates with respect to p-GaN. In fact, n-GaN is etched at a very high rate by these etchants, whereas p-GaN is etched at a negligibly low rate. As such, the second conductivity type semiconductor layers 13, 23, and 33, which may be n-GaN layers, and the undoped active layers 12, 22, and 32 may be selectively etched using a difference in etching rate according to a dopant. A top surface 101 of the light-emitting portion 100d may be protected by the passivation layer 501. The etching rates of the active layers 12, 22, and 32 may be lower than etching rates of the second conductivity type semiconductor layers 13, 23, and 33, so an etching amount may be relatively small.

According to this selective etching process, as shown in FIG. 9B, the side surfaces of the second conductivity type semiconductor layer 13 and the active layer 12 of the first light-emitting structure 10d may be stepped inward from the side surface of the first conductivity type semiconductor layer 11 of the first light-emitting structure 10d, so that a concave portion 551 is formed. Similarly, the side surfaces of the second conductivity type semiconductor layer 23 and the active layer 22 of the second light-emitting structure 20d may be stepped inward from the side surface of the first conductivity type semiconductor layer 21 of the second light-emitting structure 20d, so that a concave portion 552 is formed, and the side surfaces of the second conductivity type semiconductor layer 33 and the active layer 32 of the third light-emitting structure 30d may be stepped inward from the side surface of the first conductivity type semiconductor layer 31 of the third light-emitting structure 30d, so that a concave portion 553 is formed. A step amount of each of the concave portions 551, 552, and 553 may be determined by an etching time. For example, the etching time may be adjusted such that the step amount is equal to or less than 0.5 μm. The concave portions 551, 552, and 553 may correspond to the concave portions 13r, 23r, and 33r of FIG. 6, respectively.

### Formation of a First Common Electrode and a Second Common Portion

Next, a process of forming the first common electrode 70d and the second common portion 49d of the second common electrode 40d may be performed.

Referring to FIG. 9C, the passivation layer 501 and the light-emitting portion 100d may be etched to form via holes 511, 512, and 513 through which the first conductivity type semiconductor layers 11, 21, and 31 of the first light-emitting structure 10d, the second light-emitting structure 20d, and the third light-emitting structure 30d are exposed, respectively. This process may be performed by using, for example, a dry etching process. The dry etching process may use, for example, ICP.

Referring to FIG. 9D, a dielectric material, for example, SiO₂, may be deposited on the side portion of the light-emitting portion 100d, a surface of the passivation layer 501, and inner walls of the via holes 511, 512, and 513 to form a passivation layer 514. Portions of the passivation layer 514 on the surface of the passivation layer 501 and the bottoms of the via holes 511, 512, and 513 may be removed by using, for example, a dry etching process, and portions of the passivation layer 514 on the side portion of the light-emitting portion 100d and the inner walls of the via holes 511, 512, and 513 may remain. Accordingly, as shown in FIG. 9E, passivation layers 515dx, 516dx, and 517dx are formed on the inner walls of the via holes 511, 512, and 513, and the passivation layers 515dx, 516dx, and 517dx correspond to the passivation elements 71dx, 72dx, and 73dx of FIG. 6.

As shown in FIG. 9F, an electrode material may be deposited and filled in the via holes 511, 512, and 513 and a top surface of the passivation layer 501 to form electrodes 521, 522, and 523 and electrodes 529 and 539. The electrodes 521, 522, and 523 may be connected to each other by the electrode 529. The electrode material may include, for example, Al, Ti, Pt, Ag, Au, Pd, TiW, or any of various combinations thereof. The electrode material may also include a transparent electrode material, for example, ITO. The deposition of the electrode material may be performed by using sputtering, atomic layer deposition (ALD), plasma enhanced atomic layer deposition (PEALD), chemical vapor deposition (CVD), plasma enhanced chemical vapor deposition (PECVD), physical vapor deposition (PVD), other methods, or a combination thereof. The electrode 529 and the electrodes 521, 522, and 523 may respectively correspond to the first common portion 79 and the first electrode portions 71d, 72d, and 73d in FIG. 6. The electrode 539 may correspond to the second common portion 49d of FIG. 6.

Next, as shown in FIG. 9G, a dielectric material may be deposited to cover the electrodes 521, 522, 523, 529, and 539 to form a passivation layer 502. The dielectric material may include, for example, SiO₂, TiO₂, Si₃N₄, AlOₓ, AlOₓN_{y}, Ta₂O₅, TiN, AlN, ZrO₂, TiAlN, TiSiN, HfOₓ, ZAZ, or any of various combinations thereof. In the present embodiment, the passivation layer 502 may be formed of SiO₂, which is a light-transmitting dielectric material.

### Bonding

Next, as shown in FIG. 9G, the passivation layer 502 may be etched to expose the electrodes 529 and 539. Then, the electrode 529 and the electrode 539 may be bonded to the bonding pads 202 and 201 of the substrate 200 of the display panel.

### Formation of a Second Electrode Portion and a Separation Layer

Next, a process of forming the second electrode portion 44d of the second common electrode 40d, and the separation layer 50d may be performed.

After the light-emitting portion 100d is turned over in the state shown in FIG. 9G, the passivation layer 514 formed on the side portion of the light-emitting portion 100d may be removed. Next, a top surface of the second conductivity type semiconductor layer 33 of the third light-emitting structure 30d exposed to the upper side may be polished and planarized. In addition, a portion of the second conductivity type semiconductor layer 33 of the third light-emitting structure 30d that protrudes toward the lateral side may be polished. Next, as shown in FIG. 9H, a mask layer 515 may be formed by depositing, for example, SiN, on the side surface and top surface of the light-emitting portion 100d. The mask layer 515 may be formed by, for example, ALD.

For example, the mask layer 515 may be etched using a dry etching process so that only a portion of the mask layer 515 that covers the concave portions 551, 552, and 553 remains, as shown in FIG. 9I. An area of the side surface of the light-emitting portion 100d except for the concave portions 551, 552, and 553 may be exposed.

Next, a dielectric material may be deposited on the exposed area of the side surface of the light-emitting portion 100d by using, for example, an electron beam deposition method, to form a passivation layer 516, as shown in FIG. 9J. The mask layer 515 covering the concave portions 551, 552, and 553 may be exposed. The dielectric material may include, for example, SiO₂, TiO₂, Si₃N₄, AlOₓ, AlOₓN_{y}, Ta₂O₅, TiN, AlN, ZrO₂, TiAlN, TiSiN, HfOₓ, ZAZ, or any of various combinations thereof. In the present embodiment, the passivation layer 516 may be formed of SiO₂, which is a light-transmitting dielectric material.

Next, as shown in FIG. 9K, the mask layer 515 covering the concave portions 551, 552, and 553 may be removed. This process may be performed using an etching process that uses an etchant for selectively etching, for example, SiN. Accordingly, openings 517 exposing the concave portions 551, 552, and 553 may be formed in the passivation layer 516.

Next, an electrode material may be deposited on the side surface of the passivation layer 516 and the top surface of the light-emitting portion 100d. The electrode material may be deposited, through the openings 517, on portions of the side surfaces of the second conductivity type semiconductor layers 13, 23, and 33 of the first light-emitting structure 10d, the second light-emitting structure 20d, and the third light-emitting structure 30d that are exposed through the concave portions 551, 552, and 553. Accordingly, as illustrated in FIG. 9L, an electrode 531 in contact with the side surfaces of the second conductivity type semiconductor layers 13, 23, and 33 of the first light-emitting structure 10d, the second light-emitting structure 20d, and the third light-emitting structure 30d may be formed. The electrode material may include, for example, Al, Ti, Pt, Ag, Au, Pd, TiW, or any of various combinations thereof. The electrode 531 may include a reflective electrode material such as, for example, Al or Ag. Alternatively, the electrode 531 may include a transparent electrode material. The transparent electrode material may include, for example, ITO. The passivation layer 516 may correspond to the separation layer 50d of FIG. 6. The electrode 531 may correspond to the second electrode portion 44d of FIG. 6.

### Formation of a Lens

Next, as shown in FIG. 9M, an electrode material formed on the top surface of the light-emitting portion 100d may be removed. Then, the lens 90 may be formed on the light-emitting portion 100d. A method of forming the lens 90 is not particularly limited. In the state illustrated in FIG. 9M, a thermoplastic material may be stacked on the third light-emitting structure 30d to form a light-transmitting layer. The thermoplastic material may include, for example, photoresist, polyester, acryl, or epoxy. A shape of the light-transmitting layer may be, for example, a cylindrical shape. Next, for example, a thermal reflow process may be performed to form the light-transmitting layer having a rectangular shape into a dome-shaped lens shape. A curvature of the lens 90 may be adjusted according to surface energy of the top surface of the third light-emitting structure 30d, a contact angle of the light-transmitting layer, a thickness and a width of the light-transmitting layer, and a thermal reflow process temperature. Accordingly, the light-emitting device 1d of FIG. 6 may be manufactured.

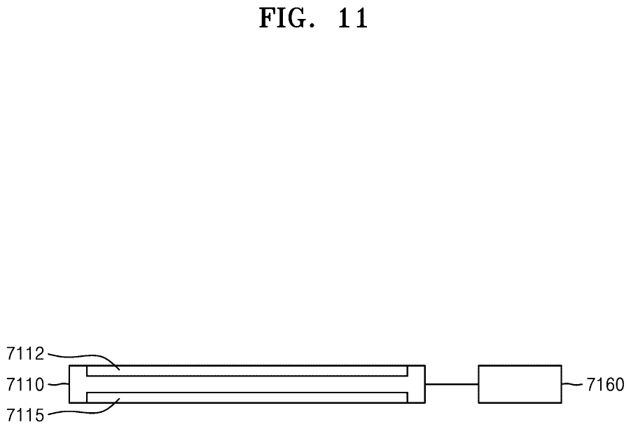

FIG. 11 is a schematic view illustrating an embodiment of a display apparatus. Referring to FIG. 11, the display apparatus may include a display panel 7110 and a controller 7160. The display panel 7110 includes a light-emitting structure 7112, and a driving circuit 7115 for switching the light-emitting structure 7112 on and off. The light-emitting structure 7112 may include a plurality of light-emitting devices described above with reference to FIGS. 1 through 6. The plurality of light-emitting devices may be arranged, for example, in a two-dimensional array. The driving circuit 7115 may include a plurality of switching devices for individually switching the plurality of light-emitting devices on and off. The controller 7160 may input an on/off switching signal of the plurality of light-emitting devices to the driving circuit 7115 according to an image signal.

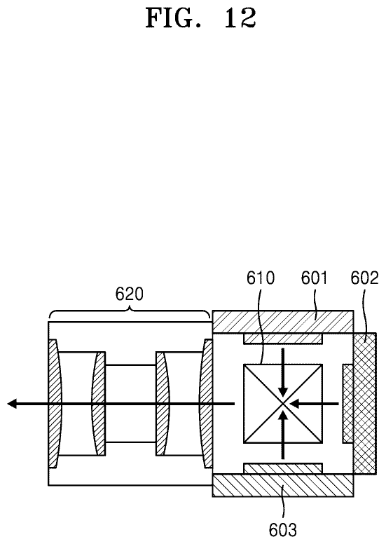

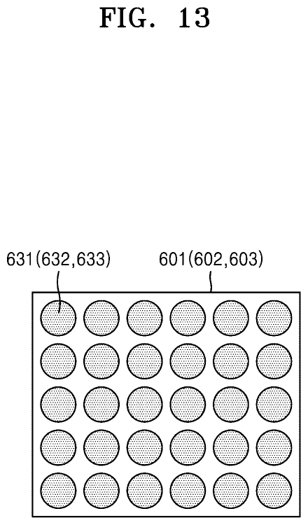

FIG. 12 is a schematic view illustrating an embodiment of a projection display apparatus. FIG. 13 illustrates an example of the arrangement of light-emitting devices of a display panel illustrated in FIG. 12. Referring to FIGS. 12 and 13, the projection display apparatus may include display panels 601, 602, and 603 that generate primary color image light beams of different colors. The display panel 601 may include a plurality of light-emitting devices 631 arranged in a two-dimensional manner. The display panel 602 may include a plurality of light-emitting devices 632 arranged in a two-dimensional manner. The display panel 603 may include a plurality of light-emitting devices 633 arranged in a two-dimensional manner. Each of the display panels 601, 602, and 603 may have a form in which the display panel 7110 and the controller 7160 in FIG. 11 are integrated with each other. In this case, each of the plurality of light-emitting devices 631, 632, and 633 may correspond to the light-emitting structure 7112. For example, the light-emitting devices 631, 632, and 633 may emit blue light, green light, and red light, respectively, and the display panels 601, 602, and 603 may generate blue image light, green image light, and red image light, respectively. The blue image light, the green image light, and the red image light may be combined into one color image light by an optical coupling member 610, and may be projected onto a target, for example, a screen or an observer's pupil, through a projection optical system 620. At least one from among the light-emitting devices 631, 632, and 633 may be a light-emitting device illustrated in FIGS. 1 through 6. For example, the light-emitting device 633 emitting red light may be the light-emitting device illustrated in FIGS. 1 through 6.

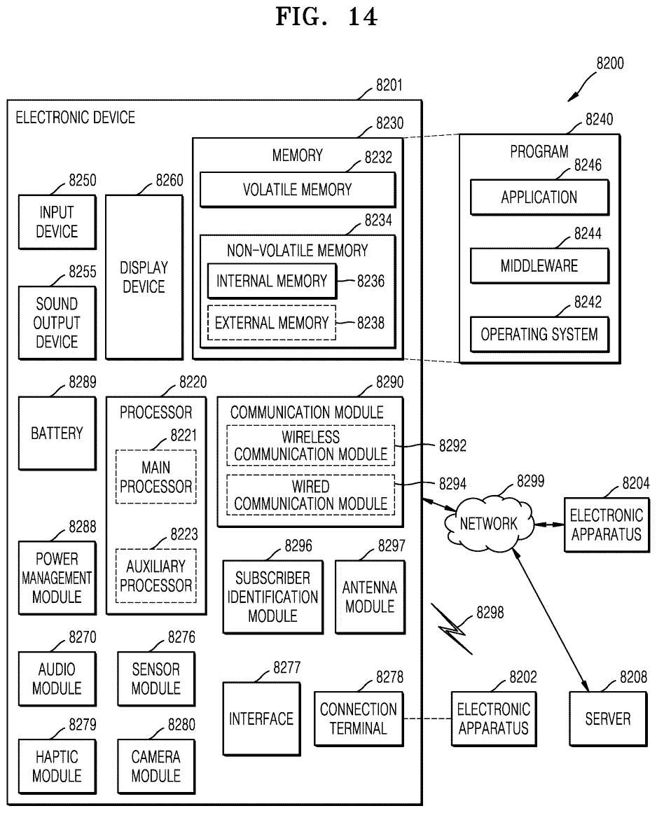

FIG. 14 is a block diagram illustrating an embodiment of an electronic device including a display. Referring to FIG. 14, an electronic device 8201 may be provided in a network environment 8200. In the network environment 8200, the electronic device 8201 may communicate with another electronic device 8202 through a first network 8298 (e.g., a short-range wireless communication network), or communicate with another electronic device 8204 and/or a server 8208 through a second network 8299 (e.g., a long-range wireless communication network). The electronic device 8201 may communicate with the electronic device 8204 via the server 8208. The electronic device 8201 may include a processor 8220, a memory 8230, an input device 8250, an audio output device 8255, a display device 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. Some of the aforementioned components may be omitted from the electronic device 8201, or other components may be added to the electronic device 8201. Some of the components may be implemented by one integrated circuit. For example, the sensor module 8276 (e.g., a fingerprint sensor, an iris sensor, or an illuminance sensor) may be embedded in the display device 8260 (e.g., a display).

The processor 8220 may control one or a plurality of other components (e.g., hardware and software components) of the electronic device 8201 connected to the processor 8220 by executing software (e.g., a program 8240), and perform various data processing or calculations. As part of the data processing or calculations, the processor 8220 may load, in a volatile memory 8232, commands and/or data received from other components (e.g., the sensor module 8276 and the communication module 8290), process the command and/or data stored in a volatile memory 8232, and store result data in a non-volatile memory 8234. The processor 8220 may include a main processor 8221 (e.g., a central processing unit or an application processor) and an auxiliary processor 8223 (e.g., a graphics processing unit, an image signal processor, a sensor hub processor, or a communication processor) that is operable independently of or together with the main processor 8221. The auxiliary processor 8223 may use less power than the main processor 8221 and may perform a specialized function.

Instead of the main processor 8221 when the main processor 8221 is in an inactive state (e.g., a sleep state), or together with the main processor 8221 when the main processor 8221 is in an active state (e.g., an application execution state), the auxiliary processor 8223 may control functions and/or states related to some components (e.g., the display device 8260, the sensor module 8276, and the communication module 8290) among the components of the electronic device 8201. The auxiliary processor 8223 (e.g., an image signal processor or a communication processor) may be implemented as a part of functionally related other components (e.g., the camera module 8280 and the communication module 8290).

The memory 2230 may store various data required by the components (e.g., the processor 8220 and the sensor module 8276) of the electronic device 8201. The data may include, for example, software (e.g., the program 8240) and input data and/or output data about commands related thereto. The memory 8230 may include the volatile memory 8232 and/or the non-volatile memory 8234.

The program 8240 may be stored as software in the memory 8230, and may include an operating system 8242, middleware 8244, and/or an application 8246.

The input device 8250 may receive commands and/or data to be used by a component (e.g., the processor 8220) of the electronic device 8201, from the outside (e.g., a user) of the electronic device 8201. The input device 8250 may include a remote controller, a microphone, a mouse, a keyboard, and/or a digital pen (e.g., a stylus pen).

The audio output device 8255 may output an audio signal to the outside of the electronic device 8201. The audio output device 8255 may include a speaker and/or a receiver. The speaker may be used for general purposes such as multimedia playback or recording playback, and the receiver can be used to receive incoming calls. The receiver may be implemented by being coupled as a part of the speaker or by an independent separate device.

The display device 8260 may visually provide information to the outside of the electronic device 8201. The display device 8260 may include a display, a hologram device, or a projector, and a control circuit for controlling a corresponding device. The display device 8260 may include the display described above with reference to FIG. 11. The display device 8260 may include a touch circuitry set to detect a touch and/or a sensor circuit (e.g., a pressure sensor) set to measure the strength of a force generated by the touch.

The audio module 8270 may convert sound into an electrical signal or reversely convert an electrical signal into sound. The audio module 8270 may obtain sound through the input device 8250, or output sound through the audio output device 8255 and/or a speaker and/or a headphone of another electronic device (e.g., the electronic device 8202) connected directly or wirelessly to the electronic device 8201.

The sensor module 8276 may detect an operation state (e.g., power or a temperature) of the electronic device 8201, or an external environment state (e.g., a user state), and generate an electrical signal and/or data value corresponding to the detected state. The sensor module 8276 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 8277 may support one or more designated protocols that may be used to directly or wirelessly connect the electronic device 8201 to another electronic device (e.g., the electronic device 8202). The interface 8277 may include a high definition multimedia interface (HDMI), a universal serial bus (USB) interface, an SD card interface, and/or an audio interface.

A connection terminal 8278 may include a connector through which the electronic device 8201 may be physically connected to another electronic device (e.g., the electronic device 8202). The connection terminal 8278 may include an HDMI connector, a USB connector, an SD card connector, and/or an audio connector (e.g., a headphone connector).

The haptic module 8279 may convert an electrical signal into a mechanical stimulus (e.g., a vibration or a movement) or an electrical stimulus that is perceivable by a user through tactile or kinesthetic sense. The haptic module 8279 may include a motor, a piezoelectric device, and/or an electrical stimulation device.

The camera module 8280 may capture a still image and a video. The camera module 8280 may include a lens assembly including one or more lenses, image sensors, image signal processors, and/or flashes. The lens assembly included in the camera module 8280 may collect light emitted from a subject whose image is captured.

The power management module 8288 may manage the power supplied to the electronic device 8201. The power management module 8288 may be implemented as a part of a power management integrated circuit (PMIC).

The battery 8289 may supply power to the components of the electronic device 8201. The battery 8289 may include a non-rechargeable primary cell, a rechargeable secondary cell, and/or a fuel cell.

The communication module 8290 may establish a direct (e.g., wired) communication channel and/or a wireless communication channel between the electronic device 8201 and another electronic device (e.g., the electronic device 8202, the electronic device 8204, or the server 8208), and support a communication through the established communication channel. The communication module 8290 may be operated independently of the processor 8220 (e.g., the application processor), and may include one or more communication processors supporting a direct communication and/or a wireless communication. The communication module 8290 may include a wireless communication module 8292 (e.g., a cellular communication module, a short-range wireless communication module, or a global navigation satellite system (GNSS) communication module), and/or a wired communication module 8294 (e.g., a local area network (LAN) communication module or a power line communication module). A corresponding communication module from among the aforementioned communication modules may communicate with another electronic device through the first network 8298 (e.g., a short-range communication network such as Bluetooth, WiFi Direct, or infrared data association (IrDA)) or the second network 8299 (e.g., a long-range communication network such as a cellular network, the Internet, or a computer network (e.g., a LAN or a wide area network (WAN)). These various types of communication modules may be integrated into one component (e.g., a single chip), or may be implemented as a plurality of separate components (e.g., a plurality of chips). The wireless communication module 8292 may verify and authenticate the electronic device 8201 in a communication network such as the first network 8298 and/or the second network 8299 by using subscriber information (e.g., an international mobile subscriber identifier (IMSI)) stored in the subscriber identification module 8296.

The antenna module 8297 may transmit a signal and/or power to the outside (e.g., another electronic device) or receive a signal and/or power from the outside. An antenna may include a radiator including a conductive pattern formed on a substrate (e.g., a printed circuit board (PCB)). The antenna module 8297 may include one or a plurality of antennas. When the antenna module 8297 includes a plurality of antennas, the communication module 8290 may select, from among the plurality of antennas, an antenna appropriate for a communication method used in a communication network such as the first network 8298 and/or the second network 8299. A signal and/or power may be transmitted or received between the communication module 8290 and another electronic device through the selected antenna. Another component part (e.g., a radio frequency integrated circuit (RFIC)) other than the antenna may be included as a part of the antenna module 8297.

Some of the components may be connected to each other through a communication method between peripheral devices (e.g., a bus, general purpose input and output (GPIO), a serial peripheral interface (SPI), or a mobile industry processor interface (MIPI)) and may mutually exchange signals (e.g., commands or data).

The commands or data may be transmitted or received between the electronic device 8201 and the external electronic device 8204 through the server 8208 connected to the second network 8299. The electronic devices 8202 and 8204 may be of the same or different types compared to the electronic device 8201. All or some of operations executed in the electronic device 8201 may be executed in one or more devices among the other electronic devices, namely, the electronic devices 8202 and 8204 and the server 8208. For example, when the electronic device 8201 needs to perform certain functions or services, the electronic device 8201 may request one or more other electronic devices to perform some or all of the functions or services, instead of directly performing the functions or services. The one or more electronic devices receiving the request may execute additional functions or services related to the request, and transmit a result of the execution to the electronic device 8201. To this end, a cloud computing technology, a distributed computing technology, or a client-server computing technology may be used.

The electronic device 8201 may be applied to various devices. Various components of the electronic device 8201 may be appropriately modified according to a function of the device, and components suitable to perform a function of the device may be added. Application examples of the electronic device 8201 will now be described.

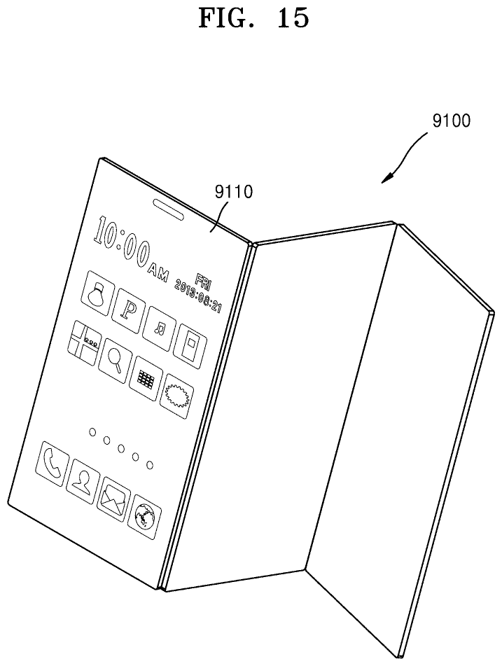

FIG. 15 illustrates an embodiment of a mobile device as an application example of an electronic device. A mobile device 9100 may include a display apparatus 9110. The display apparatus 9110 may include the display apparatus described above with reference to FIG. 11. The display apparatus 9110 may have a foldable structure, for example, a multi-foldable structure.

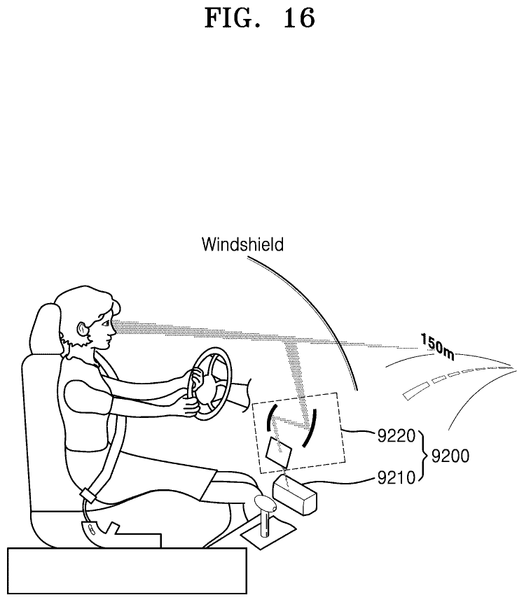

FIG. 16 illustrates an embodiment of a head-up display apparatus for a vehicle as an application example of an electronic device. A head-up display apparatus 9200 for a vehicle may include a display 9210 provided in an area of the vehicle, and an optical path changing member 9220 configured to change a path of light so that a driver may see an image generated on the display 9210. The display 9210 may include the display apparatus described above with reference to FIG. 11.

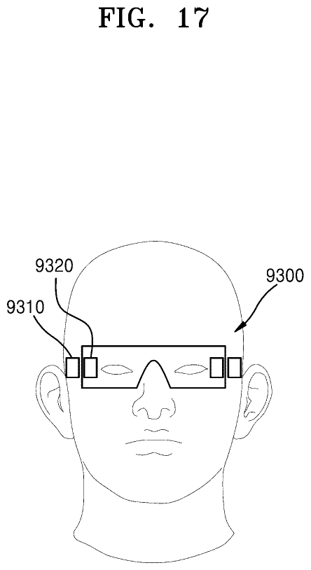

FIG. 17 illustrates an embodiment of augmented reality glasses or virtual reality glasses as an application example of an electronic device. Augmented reality glasses (or virtual reality glasses) 9300 may include a projection system 9310 that forms an image, and an element 9320 that guides an image from the projection system 9310 into a user's eyes. The projection system 9310 may include the display apparatus described above with reference to FIG. 11.

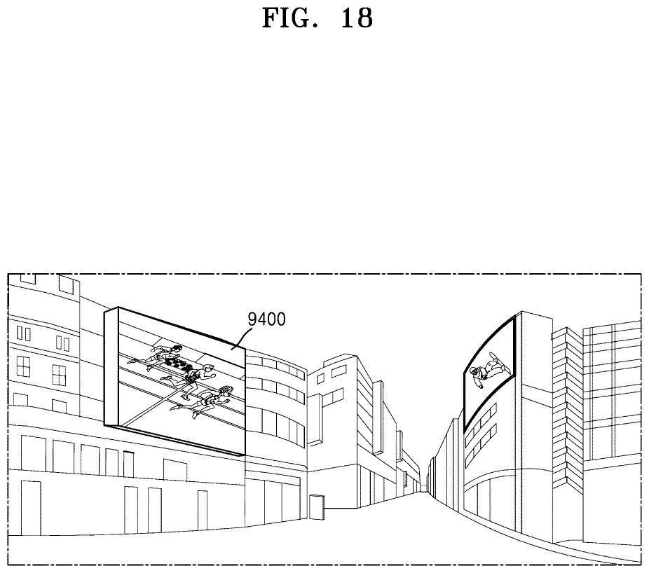

FIG. 18 illustrates an embodiment of a large signage as an application example of an electronic device. A signage 9400 may include the display apparatus described above with reference to FIG. 11. The signage 9400 may be used for outdoor advertisement using a digital information display, and may control advertisement content or the like through a communication network. The signage 9400 may be implemented through, for example, the electronic device described above with reference to FIG. 13.

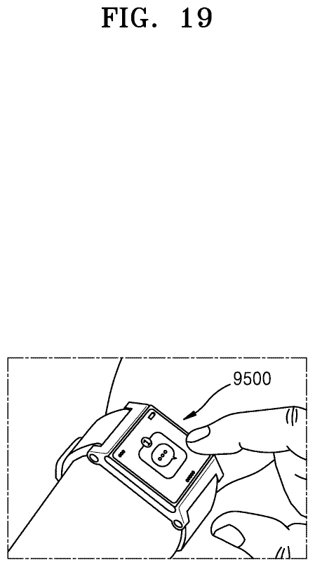

FIG. 19 illustrates an embodiment of a wearable display as an application example of an electronic device. A wearable display 9500 may include the display apparatus described above with reference to FIG. 11. The wearable display 9500 may be implemented through the electronic device described above with reference to FIG. 14.

A light-emitting device or a display including the light-emitting device, according to an embodiment, may also be applied to various other products such as a rollable TV and a stretchable display.

Although a light-emitting device according to the disclosure has been described above with reference to the embodiments illustrated in the drawings to help understanding, the illustrated embodiments are only examples, and those skilled in the art will understand that various modifications to the illustrated embodiments and other equivalent embodiments are possible. Thus, the various modifications are included within the spirit and scope of the disclosure.

According to embodiments, it is possible to implement a light-emitting device capable of obtaining a sufficient amount of light with a low driving voltage by electrically connecting a plurality of vertically stacked light-emitting structures in parallel by using first and second common electrodes.

In addition, by reducing the number of conductive via structures, luminous efficiency may be improved, and power consumption may be reduced.

Embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure.

What is claimed is:

1. A light-emitting device comprising:
a light-emitting portion comprising a first light-emitting structure and a second light-emitting structure on the first light-emitting structure in a first direction, the first light-emitting structure and the second light-emitting structure configured to emit light of a same wavelength as each other, wherein a width of the second light-emitting structure is greater than a width of the first light-emitting structure, each of the first light-emitting structure and the second light-emitting structure comprises a first conductivity type semiconductor layer, an active layer, and a second conductivity type semiconductor layer, and the active layer is between the first conductivity type semiconductor layer and the second conductivity type semiconductor layer in the first direction;
a first common electrode comprising:
a first common portion under the light-emitting portion in a second direction opposite to the first direction; and
a plurality of first electrode portions extending from the first common portion such as to respectively contact the first conductivity type semiconductor layer of the first light-emitting structure and the first conductivity type semiconductor layer of the second light-emitting structure, wherein at least one of the plurality of first electrode portions comprises a conductive via structure;
a second common electrode comprising:
a second common portion under the light-emitting portion in the second direction; and
a plurality of second electrode portions extending from the second common portion in the first direction such as to respectively contact a side surface of the second conductivity type semiconductor layer of the first light-emitting structure and a side surface of the second conductivity type semiconductor layer of the second light-emitting structure, wherein the plurality of second electrode portions are spaced apart from each other in a third direction crossing the first direction; and
a plurality of separation layers configured to insulate the side surface of the second conductivity type semiconductor layer of the first light-emitting structure, the side surface of the second conductivity type semiconductor layer of the second light-emitting structure, a side surface of the active layer of the first light-emitting structure, and a side surface of the active layer of the second light-emitting structure from the plurality of second electrode portions.

2. The light-emitting device of claim 1, wherein the plurality of second electrode portions surrounds a side portion of the light-emitting portion.

3. The light-emitting device of claim 1, further comprising a protective layer between the plurality of second electrode portions.

4. The light-emitting device of claim 1, wherein, in each of the first light-emitting structure and the second light-emitting structure, the active layer is on the first conductivity type semiconductor layer in the first direction, and the second conductivity type semiconductor layer is on the active layer in the first direction.

5. The light-emitting device of claim 4, wherein, in the first light-emitting structure and the second light-emitting structure, a width of the active layer and a width of the first conductivity type semiconductor layer are less than a width of the second conductivity type semiconductor layer,
the plurality of second electrode portions respectively contact side surfaces of the second conductivity type semiconductor layer of the first light-emitting structure and the second conductivity type semiconductor layer of the second light-emitting structure, and
the plurality of second electrode portions are spaced apart from each other in the third direction on a side portion of the light-emitting portion.

6. The light-emitting device of claim 4, wherein two separation layers from among the plurality of separation layers extend beyond the active layer of the first light-emitting structure and the active layer of the second light-emitting structure, respectively.

7. The light-emitting device of claim 4, wherein a first electrode portion, from among the plurality of first electrode portions, contacts the first conductivity type semiconductor layer of the second light-emitting structure, and the first electrode portion comprises the conductive via structure.

8. The light-emitting device of claim 1, wherein, in the first light-emitting structure and the second light-emitting structure, the active layer is on the second conductivity type semiconductor layer in the first direction, and the first conductivity type semiconductor layer is on the active layer in the first direction.

9. The light-emitting device of claim 8, wherein a width of the second conductivity type semiconductor layer of the second light-emitting structure is less than a width of the active layer of the second light-emitting structure and a width of the first conductivity type semiconductor layer of the second light-emitting structure,
the second common portion contacts a lower surface of the second conductivity type semiconductor layer of the first light-emitting structure,
at least one of the plurality of second electrode portions contacts the side surface of the second conductivity type semiconductor layer of the second light-emitting structure, and
the plurality of second electrode portions are spaced apart from each other in the third direction on a side portion of the light-emitting portion.

10. The light-emitting device of claim 9, wherein a separation layer, from among the plurality of separation layers, is between one of the plurality of second electrode portions and the first light-emitting structure, and
the one of the plurality of second electrode portions contacts the side surface of the second conductivity type semiconductor layer of the second light-emitting structure.

11. The light-emitting device of claim 10, wherein a first separation layer, from among the plurality of separation layers, extends to the second conductivity type semiconductor layer of the first light-emitting structure, and
a second separation layer, from among the plurality of separation layers, extends to the second conductivity type semiconductor layer of the second light-emitting structure.

12. The light-emitting device of claim 9, wherein the plurality of first electrode portions comprises conductive via structures.

13. The light-emitting device of claim 1, wherein the first light-emitting structure and the second light-emitting structure are configured to emit one from among blue light, green light, and red light.

14. The light-emitting device of claim 1, wherein the first light-emitting structure and the second light-emitting structure are configured to emit red light.

15. The light-emitting device of claim 1, further comprising a lens on the light-emitting portion in the first direction.

16. The light-emitting device of claim 1, wherein the second common electrode comprises a reflective electrode material.

17. The light-emitting device of claim 1, wherein the first conductivity type semiconductor layer and the second conductivity type semiconductor layer are a p-type semiconductor layer and an n-type semiconductor layer, respectively,
the first common electrode is a p-common electrode, and
the second common electrode is an n-common electrode.

18. A light-emitting device comprising:
a light-emitting portion comprising a first light-emitting structure and a second light-emitting structure on the first light-emitting structure in a first direction, the first light-emitting structure and the second light-emitting structure configured to emit light of a same wavelength as each other, each of the first light-emitting structure and the second light-emitting structure comprising a first conductivity type semiconductor layer, an active layer, and a second conductivity type semiconductor layer,
wherein the active layer is between the first conductivity type semiconductor layer and the second conductivity type semiconductor layer in the first direction,
wherein a side surface of the second conductivity type semiconductor layer of the first light-emitting structure comprises a first concave portion comprising a stepped shape that is concave with respect to a side surface of the active layer of the first light-emitting structure and a side surface of the first conductivity type semiconductor layer of the first light-emitting structure,
wherein a side surface of the second conductivity type semiconductor layer of the second light-emitting structure comprises a second concave portion comprising a stepped shape that is concave with respect to a side surface of the active layer of the second light-emitting structure and a side surface of the first conductivity type semiconductor layer of the second light-emitting structure, and
wherein the light-emitting device further comprises:
a first common electrode comprising:
a first common portion under the light-emitting portion in a second direction opposite to the first direction; and
plurality of first electrode portions extending from the first common portion such as to respectively contact the first conductivity type semiconductor layer of the first light-emitting structure and the first conductivity type semiconductor layer of the second light-emitting structure, wherein at least one of the plurality of first electrode portions comprises a conductive via structure;
a separation layer on a side portion of the light-emitting portion, wherein the first concave portion and the second concave portion are exposed from the separation layer; and
a second common electrode comprising:
a second common portion under the light-emitting portion in the second direction; and
a second electrode portion extending from the second common portion in the first direction along an outer surface of the separation layer such as to contact, via the first concave portion, the side surface of the second conductivity type semiconductor layer of the first light-emitting structure, and contact, via the second concave portion, the side surface of the second conductivity type semiconductor layer of the second light-emitting structure.

19. A display apparatus comprising:
a display panel comprising:
a plurality of light-emitting devices; and
a driving circuit configured to switch the plurality of light-emitting devices on and off; and
a controller configured to input an on-off switching signal of the plurality of light-emitting devices to the driving circuit according to an image signal,
wherein at least one of the plurality of light-emitting devices comprises the light-emitting device of claim 1.

20. The display apparatus of claim 19, wherein the light-emitting device is configured to emit red light.
